(19) United States
(12) Patent Application Publication
(10) Pub. No.: US 2026/0130073 A1
(43) Pub. Date: May 7, 2026

(54) ELECTRONIC DEVICE

(71) Applicant: Samsung Display Co., Ltd., Yongin-Si (KR)

(72) Inventors: JAEKEUN LIM, Yongin-si (KR); HAE-KWAN SEO, Yongin-si (KR); BON-SEOG GU, Yongin-si (KR); JINYOUNG ROH, Yongin-si (KR)

(21) Appl. No.: 19/376,546

(22) Filed: Oct. 31, 2025

(30) Foreign Application Priority Data
Nov. 6, 2024 (KR) 10-2024-0155857

(51) Int. Cl. H10K 59/131

(52) U.S. Cl. CPC H10K 59/131

(57) ABSTRACT

Disclosed is an electronic device including a display panel. The display panel includes first-first type pixels that output light of a first color, first-second type pixels that output the light of the first color, second-first type pixels that output light of a second color different from the light of the first color, second-second type pixels that output the light of the second color, a first-first type data line connected with the first-first type pixels, a second type data line connected with the second-first type pixels and the second-second type pixels, and a first-second type data line connected with the first-second type pixels.

### CROSS REFERENCE TO RELATED APPLICATIONS

This application claims priority under 35 U.S.C. § 119 to Korean Patent Application No. 10-2024-0155857 filed on November 06, 2024, in the Korean Intellectual Property Office, the disclosures of which are incorporated by reference herein in their entireties.

### BACKGROUND

Embodiments of the present disclosure described herein relate to an electronic device, and more particularly, relate to an electronic device capable of switching to a wide viewing angle mode or a narrow viewing angle mode.

Multimedia electronic devices, such as a television, a mobile phone, a tablet computer, a car navigation device, a game machine, and the like, include an electronic device for displaying an image. In addition, vehicles include an electronic device inside.

Depending on a use environment in which information has to be protected or regulations for safety, there is a need to limit the viewing angle of a display device. Accordingly, studies are being conducted to limit the viewing angle.

### SUMMARY

Embodiments of the present disclosure provide an electronic device capable of switching to a wide viewing angle mode or a narrow viewing angle mode and reducing power consumption.

According to an embodiment, an electronic device includes a display panel and a panel driver that drives the display panel in a first mode or a second mode.

The display panel includes first-first type pixels that output light of a first color, first-second type pixels that output the light of the first color, second-first type pixels that output light of a second color different from the light of the first color, second-second type pixels that output the light of the second color, a first-first type data line connected with the first-first type pixels, a second type data line connected with the second-first type pixels and the second-second type pixels, and a first-second type data line connected with the first-second type pixels.

In the first mode, the first-first type data line may receive a first-first effective data signal, the second type data line may receive a second effective data signal, and the first-second type data line may receive a first-second effective data signal. In the second mode, the first-first type data line may receive the first-first effective data signal, the second type data line may receive the second effective data signal and a non-effective data signal in alternating order, and the first-second type data line may receive the non-effective data signal.

In an embodiment, each of the first-first type pixels may include a first-first light emitting element, and each of the first-second type pixels may include a first-second light emitting element. The first-first light emitting element and the first-second light emitting element may be spaced apart from each other in a first direction, and the first-first type data line, the second type data line, and the first-second type data line may extend in a second direction perpendicular to the first direction.

The first-first type pixels may include first-first pixel circuits arranged in the second direction, and the first-second type pixels may include first-second pixel circuits arranged in the second direction. The first-first pixel circuits may be connected with the first-first type data line, and the first-second pixel circuits may be connected with the first-second type data line.

Each of the second-first type pixels may include a second-first light emitting element and a second-first pixel circuit. Each of the second-second type pixels may include a second-second light emitting element and a second-second pixel circuit. The second-first pixel circuit and the second-second pixel circuit may be connected with the second type data line.

In an embodiment, the second-first light emitting element may not overlap the second-first pixel circuit when viewed from above a plane and the second-second light emitting element may overlap the second-second pixel circuit when viewed from above the plane. An anode of the second-first light emitting element may extend toward the second-first pixel circuit.

The second-first light emitting element may overlap the second-first pixel circuit when viewed from above a plane. The second-second light emitting element may not overlap the second-second pixel circuit when viewed from above the plane, and an anode of the second-second light emitting element may extend toward the second-second pixel circuit.

In an embodiment the display panel may further include third-first type pixels configured to output light of a third color different from the light of the first color and the light of the second color. The display panel may also further include third-second type pixels configured to output the light of the third color. A third type data line may be connected with the third-first type pixels and the third-second type pixels.

In the first mode, the third type data line may receive a third effective data signal, and in the second mode, the third type data line may receive the third effective data signal and the non-effective data signal in alternating order.

The display panel may operate using a first pixel unit and a second pixel unit in the first mode and operate using a third pixel unit in the second mode. The third pixel unit may have a different configuration of pixels than configurations of pixels in the first pixel unit and the second pixel unit.

The first pixel unit may include a first-first type pixel, a first-second type pixel, a second-first type pixel, and a third-second type pixel. The second pixel unit may include a first-first type pixel, a first-second type pixel, a second-second type pixel, and a third-first type pixel. The third pixel unit may include two first-first type pixels, a second-first type pixel, and a third-first type pixel.

In an embodiment the light of the first color may be green light, the light of the second color may be red light, and the light of the third color may be blue light.

The non-effective data signal may have a voltage level corresponding to a black grayscale.

The first mode may be a mode configured to output an image at a first viewing angle and the second mode may be a mode configured to output the image at a second viewing angle narrower than the first viewing angle.

In an embodiment, an optical path control layer may be disposed over the display panel and configured to adjust a light output range of the light of the first color and the light of the second color output from the first-first type pixels and the second-first type pixels.

Each of the first-first type pixels may include a first-first light emitting element, and each of the first-second type pixels may include a first-second light emitting element. Each of the second-first type pixels may include a second-first light emitting element, and each of the second-second type pixels may include a second-second light emitting element. The optical path control layer may include a light absorbing barrier wall disposed over the first-first light emitting elements and the second-first light emitting elements and configured to overlap the first-first light emitting elements and the second-first light emitting elements when viewed from above a plane.

According to an embodiment, an electronic device includes a display panel and a panel driver that drives the display panel in a first mode or a second mode in response to a first mode enable signal or a second mode enable signal received from one or more main processors.

The display panel includes a first-first type pixel that outputs light of a first color, a first-second type pixel that outputs the light of the first color, a second-first type pixel that outputs light of a second color different from the light of the first color, a second-second type pixel that outputs the light of the second color, a third-first type pixel that outputs light of a third color different from the light of the first color and the light of the second color, and a third-second type pixel that outputs the light of the third color.

The display panel operates using a first pixel unit and a second pixel unit in the first mode and operates using a third pixel unit having a configuration different from configurations of the first pixel unit and the second pixel unit in the second mode. The first pixel unit includes the first-first type pixel, the first-second type pixel, the second-first type pixel, and the third-second type pixel. The second pixel unit includes the first-first type pixel, the first-second type pixel, the second-second type pixel, and the third-first type pixel. The third pixel unit includes two first-first type pixels, the second-first type pixel, and the third-first type pixel.

The first-first type pixel may include a first-first light emitting element, and the first-second type pixel may include a first-second light emitting element. The second-first type pixel may include a second-first light emitting element, and the second-second type pixel may include a second-second light emitting element. The third-first type pixel may include a third-first light emitting element, and the third-second type pixel may include a third-second light emitting element.

The first-first light emitting element and the first-second light emitting element may be spaced apart from each other in a first direction. The second-first light emitting element and the third-second light emitting element may be adjacent to each other in a second direction perpendicular to the first direction. The second-second light emitting element and the third-first light emitting element may be adjacent to each other in the second direction.

The first-first type pixel may further include a first-first pixel circuit, and the first-second type pixel may further include a first-second pixel circuit. The second-first type pixel may further include a second-first pixel circuit, and the second-second type pixel may further include a second-second pixel circuit. The third-first type pixel may further include a third-first pixel circuit, and the third-second type pixel may further include a third-second pixel circuit.

In an embodiment, the display panel may further include a first-first type data line connected to the first-first pixel circuit, a second type data line connected to the second-first pixel circuit and the second-second pixel circuit, a first-second type data line connected to the first-second pixel circuit, and a third type data line connected to the third-first pixel circuit and the third-second pixel circuit.

### BRIEF DESCRIPTION OF THE FIGURES

The above and other objects and features of the present disclosure will become apparent by describing in detail embodiments thereof with reference to the accompanying drawings.

FIG. 1A is a front view of an electronic device according to an embodiment of the present disclosure.

FIG. 1B is a perspective view of the electronic device according to an embodiment of the present disclosure.

FIG. 2 is a view illustrating the interior of a vehicle in which an electronic device according to an embodiment of the present disclosure is disposed.

FIG. 3A is a view illustrating a state in which a second display area of an electronic device operates in a first mode according to an embodiment of the present disclosure.

FIG. 3B is a view illustrating a state in which the second display area of the electronic device operates in a second mode according to an embodiment of the present disclosure.

FIG. 4A is a view illustrating a state in which a first display area of the electronic device operates in the first mode according to an embodiment of the present disclosure.

FIG. 4B is a view illustrating a state in which the first display area of the electronic device operates in the second mode according to an embodiment of the present disclosure.

FIG. 5 is a sectional view of an electronic device according to an embodiment of the present disclosure.

FIG. 6 is a block diagram of an electronic device according to an embodiment of the present disclosure.

FIG. 7A is an enlarged sectional view illustrating a portion corresponding to a wide pixel of the electronic device illustrated in FIG. 6.

FIG. 7B is an enlarged sectional view illustrating a portion corresponding to a narrow pixel of the electronic device illustrated in FIG. 6.

FIG. 8A is a view illustrating a display panel operating in the first mode according to an embodiment of the present disclosure.

FIG. 8B is a view illustrating the display panel operating in the second mode according to an embodiment of the present disclosure.

FIG. 9A illustrates waveform diagrams of data signals applied to a first-first type data line, a first-second type data line, a second type data line, and a third type data line in the first mode according to an embodiment of the present disclosure.

FIG. 9B illustrates waveform diagrams of data signals applied to the first-first type data line, the first-second type data line, the second type data line, and the third type data line in the second mode according to an embodiment of the present disclosure.

FIG. 10A is a view illustrating the display panel operating in the first mode according to an embodiment of the present disclosure.

FIG. 10B is a view illustrating the display panel operating in the second mode according to an embodiment of the present disclosure.

FIG. 11A illustrates waveform diagrams of data signals applied to a first-first type data line, a first-second type data line, a second type data line, and a third type data line in the first mode according to an embodiment of the present disclosure.

FIG. 11B illustrates waveform diagrams of data signals applied to the first-first type data line, the first-second type data line, the second type data line, and the third type data line in the second mode according to an embodiment of the present disclosure.

FIG. 12A is a view illustrating the display panel operating in the first mode according to an embodiment of the present disclosure.

FIG. 12B is a view illustrating the display panel operating in the second mode according to an embodiment of the present disclosure.

FIG. 13A is a view illustrating the display panel operating in the first mode according to an embodiment of the present disclosure.

FIG. 13B is a view illustrating the display panel operating in the second mode according to an embodiment of the present disclosure.

FIG. 14 is a block diagram of the electronic device according to an embodiment of the present disclosure.

FIG. 15 illustrates schematic views of electronic devices according to various embodiments.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

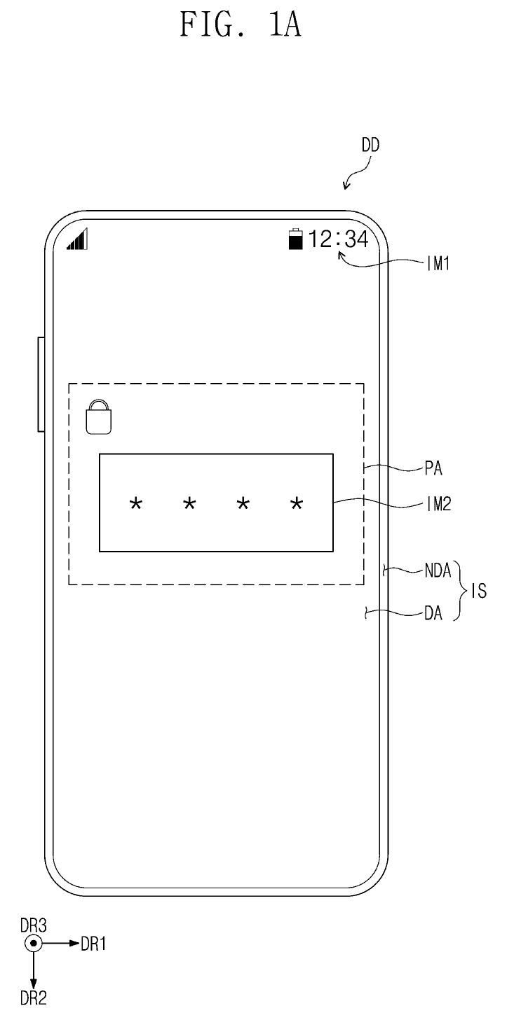

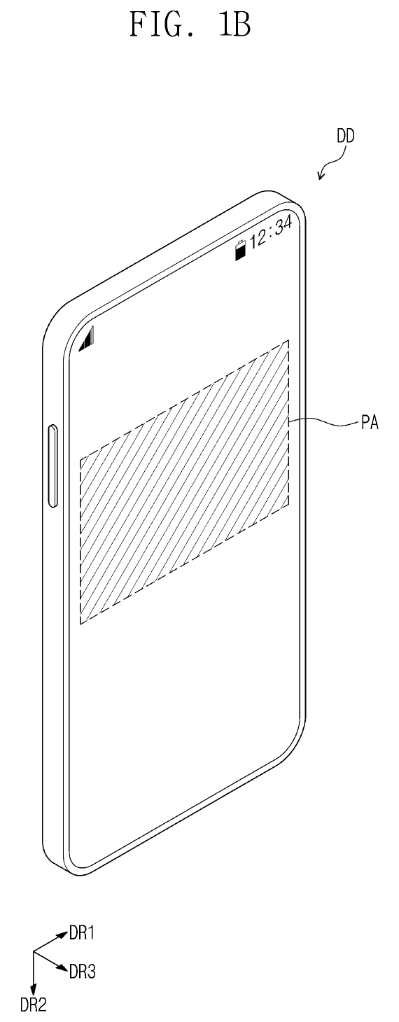

FIG. 1A is a front view of an electronic device according to an embodiment of the present disclosure. FIG. 1B is a perspective view of the electronic device according to an embodiment of the present disclosure.

Referring to FIGS. 1A and 1B, the electronic device DD may be a device activated in response to an electrical signal. The electronic device DD may be a mobile phone, a tablet computer, a smart watch, a notebook computer, a computer, a smart television, or the like.

The electronic device DD may display images IM1 and IM on a display surface IS parallel to a direction DR1 and a second direction DR2 crossing the first direction DR1. The display surface IS may correspond to the front surface of the electronic device DD. The images IM1 and IM2 may include a still image as well as a dynamic image. The normal direction of the display surface IS, that is, the thickness direction of the electronic device DD may be indicated by a third direction DR3. Front surfaces (or, upper surfaces) and rear surfaces (or, lower surfaces) of layers or units to be described below may be distinguished from each other based on the third direction DR3.

The display surface IS of the electronic device DD may be divided into a display area DA and a non-display area NDA. The display area DA may be an area on which the images IM1 and IM2 are displayed. A user may visually recognize the images IM1 and IM2 through the display area DA. In this embodiment, the display area DA is illustrated in a rounded rectangular shape. However, this is illustrative, and the display area DA may have various shapes and is not limited to any one embodiment.

The non-display area NDA may be adjacent to the display area DA. The non-display area NDA may have a certain color. The non-display area NDA may surround the display area DA. Accordingly, the shape of the display area DA may be substantially defined by the non-display area NDA. However, this is illustrative, and the non-display area NDA may be disposed adjacent to only one side of the display area DA or may be omitted. The electronic device DD according to an embodiment of the present disclosure may include various embodiments and is not limited to any one embodiment.

The electronic device DD may operate in a first mode or a second mode. The first mode may be a normal mode, a public mode, or a wide viewing angle mode for displaying a screen at a first viewing angle. The second mode may be a viewing angle control mode for displaying a screen at a second viewing angle narrower than the first viewing angle. The second mode may be referred to as a privacy mode, a privacy protection mode, or a narrow viewing angle mode. The first viewing angle and the second viewing angle may be defined as angles at which the user is capable of viewing a screen without image quality distortion based on the normal direction of the display surface IS.

The images IM1 and IM2 may include the first image IM1 and the second image IM2. The first image IM1 may be an image displayed in one area operating in the first mode. The second image IM2 may be an image displayed in a privacy protection area PA operating in the second mode.

In FIGS. 1A and 1B, the first image IM1 is illustrated as an image showing a status such as battery level, current time, and the like, and the second image IM2 is illustrated as an image requiring privacy protection, such as a field for entering a password. However, this is illustrative, and the configurations of the first image IM1 and the second image IM2 according to an embodiment of the present disclosure are not limited thereto. For example, the entire display area DA may be defined as the privacy protection area PA.

When the electronic device DD is viewed from the front (or, in a direction parallel to the normal direction or in the third direction DR3) in the first mode or the second mode, the first image IM1 and the second image IM2 generated by the electronic device DD may be visually recognized by the user.

When the electronic device DD is viewed at an angle exceeding the second viewing angle in the second mode, the second image IM2 may not be visible. For reference, when the electronic device DD is viewed at an angle exceeding the second viewing angle in the first mode, the user may visually recognize the second image IM2.

The second viewing angle in the second mode and the luminance at the second viewing angle may be set in various ways. For example, the second viewing angle may be about 45 degrees, and the luminance at about 45 degrees may be about 10 percent of the maximum luminance. However, the present disclosure is not particularly limited thereto.

The electronic device DD may selectively operate in either the first mode for displaying a screen at the first viewing angle or the second mode for displaying a screen at the second viewing angle narrower than the first viewing angle. The switching between the first mode and the second mode may be set by the user, or the electronic device DD may switch from the first mode to the second mode when a specific application is executed. For example, when an application having a risk of leaking personal information, such as a banking application or a memo application, is executed, the electronic device DD may switch from the first mode to the second mode.

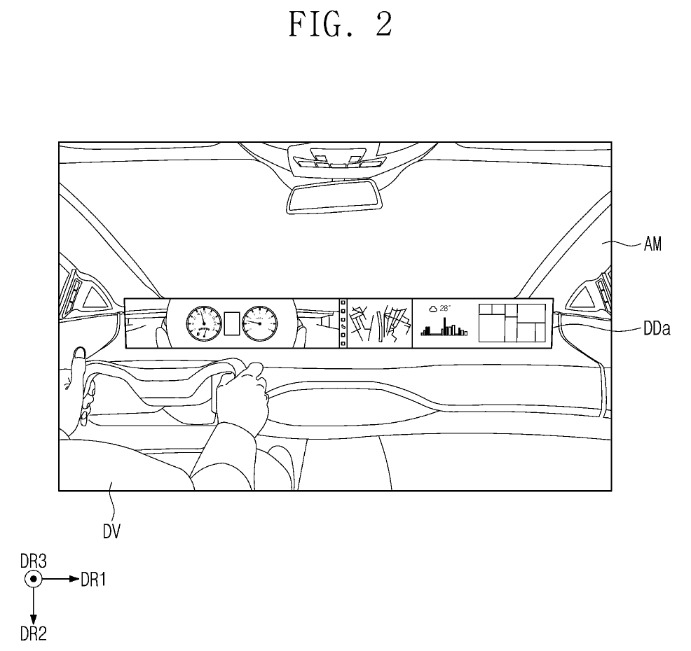

FIG. 2 is a view illustrating the interior of a vehicle in which an electronic device according to an embodiment of the present disclosure is disposed.

Referring to FIG. 2, the electronic device DDa may be disposed inside the vehicle AM. The electronic device DDa disposed inside the vehicle AM may provide various pieces of information to a driver DV (or, a user). The electronic device DDa may provide an image such as weather, speed, map, or movie to the driver DV. The electronic device DDa may be a touch-based electronic device capable of operating in response to a touch input of the driver DV.

Although the vehicle electronic device DDa is illustrated as an example in FIG. 2, embodiments of the present disclosure are not limited thereto. For example, the electronic device DDa according to an embodiment of the present disclosure may be used in electronic devices, such as a smart phone, a digital camera, a notebook computer, a monitor, and a smart television, which provide an image to the user.

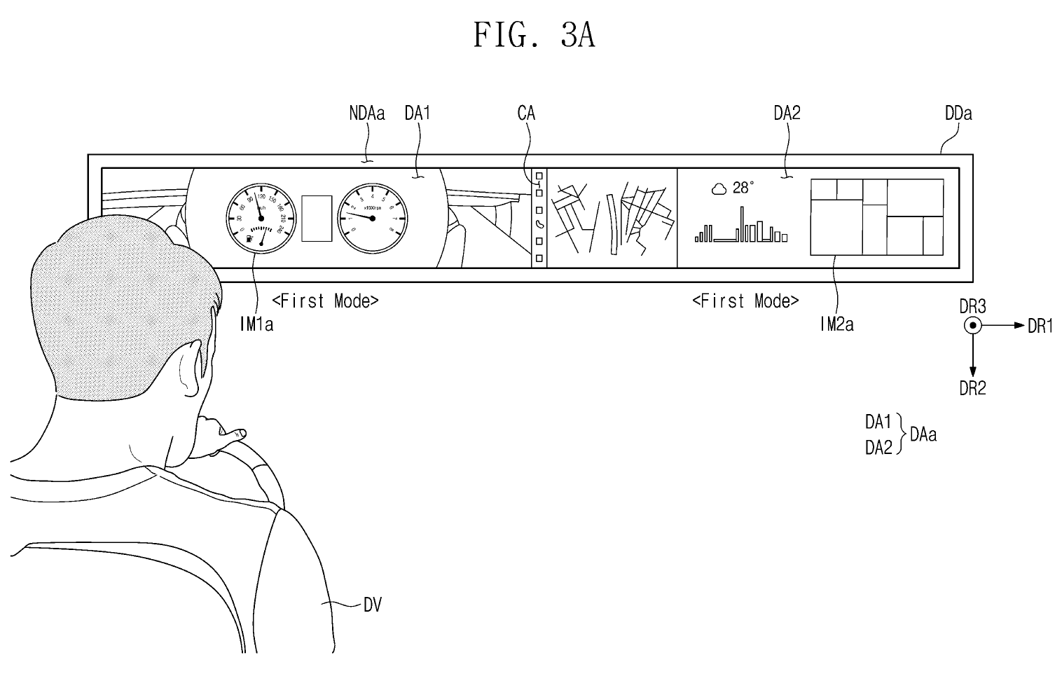

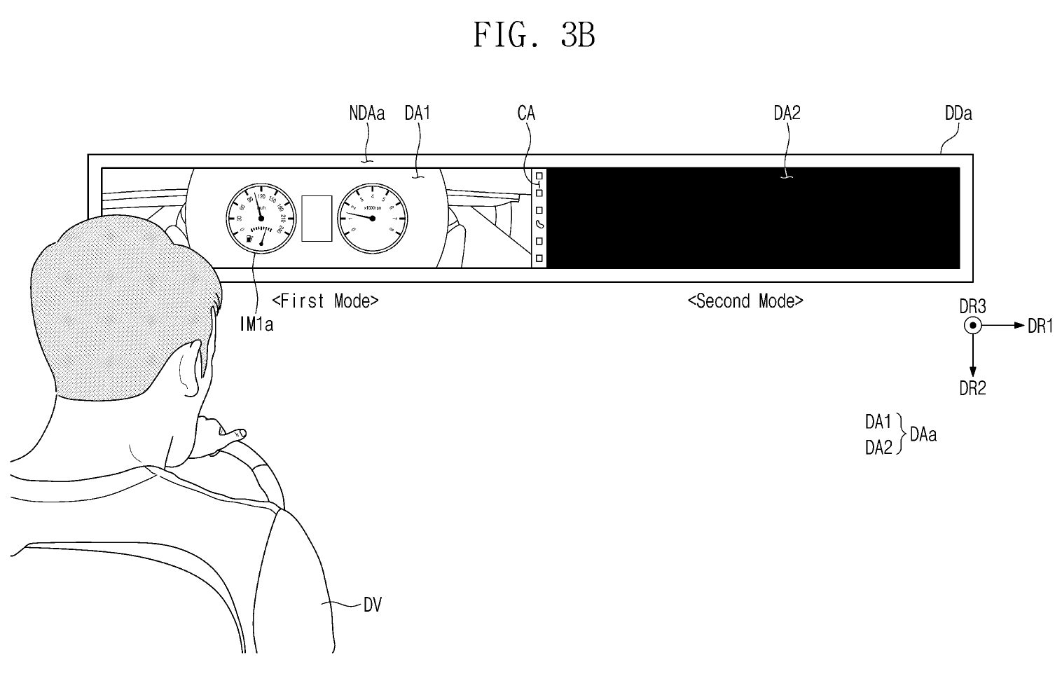

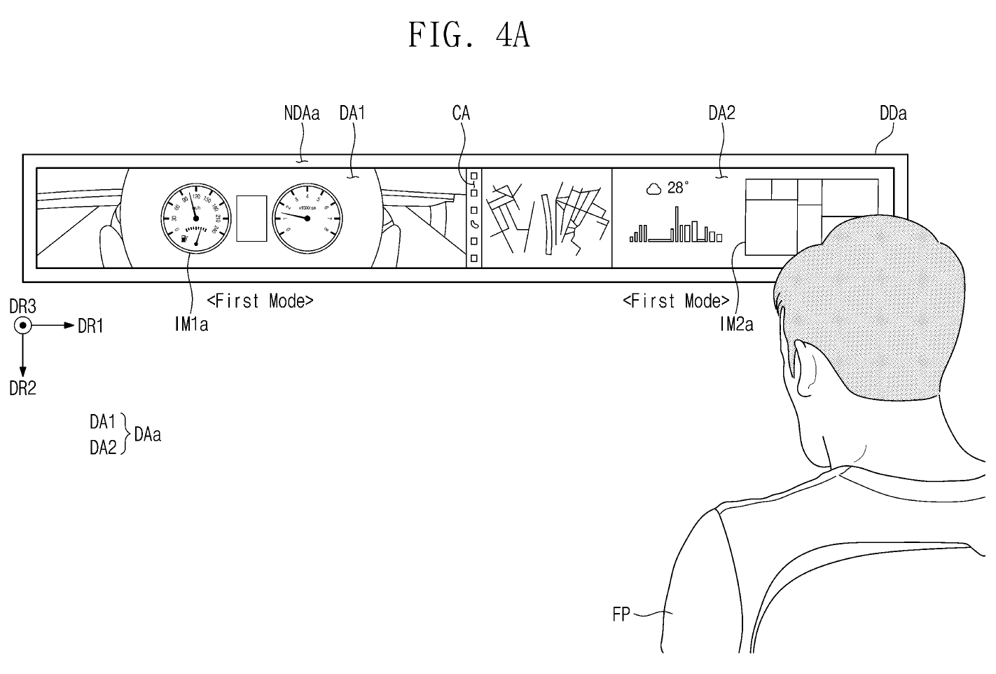

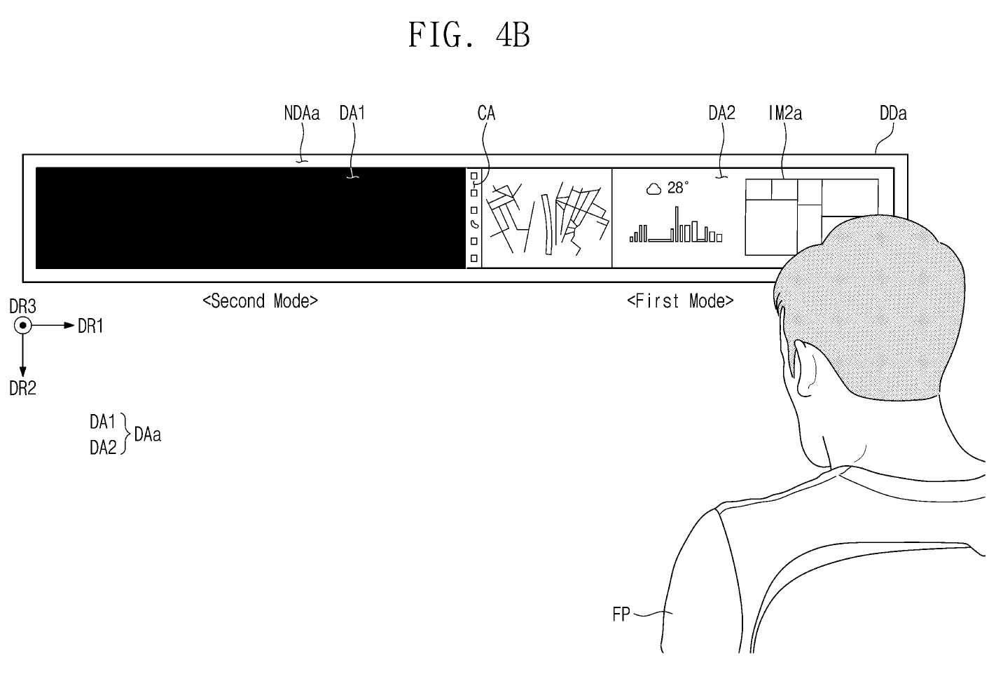

FIG. 3A is a view illustrating a state in which a second display area of an electronic device operates in a first mode according to an embodiment of the present disclosure. FIG. 3B is a view illustrating a state in which the second display area of the electronic device operates in a second mode according to an embodiment of the present disclosure. FIG. 4A is a view illustrating a state in which a first display area of the electronic device operates in the first mode according to an embodiment of the present disclosure. FIG. 4B is a view illustrating a state in which the first display area of the electronic device operates in the second mode according to an embodiment of the present disclosure.

Referring to FIGS. 3A and 3B, the electronic device DDa may have a plane defined by the first direction DR1 and the second direction DR2 crossing each other. The electronic device DDa may have long sides extending in the first direction DR1 and short sides extending in the second direction DR2. The electronic device DDa may have a rectangular shape. However, without being limited thereto, the electronic device DDa may have various shapes. In addition, the corners of the electronic device DDa that connect the long sides and the short sides may have a curved shape.

The front surface of the electronic device DDa may be defined as a display surface and may have a plane defined by the first direction DR1 and the second direction DR2. Images generated by the electronic device DDa may be provided to a user through the display surface.

The electronic device DDa may include a display area DAa and a non-display area NDAa around the display area DAa. The display area DAa may display an image, and the non-display area NDAa may not display an image. The non-display area NDAa may surround the display area DAa and may define the border of the electronic device DDa that is printed in a certain color.

In an embodiment of the present disclosure, the display area DAa may include a first display area DA1 and a second display area DA2. The first display area DA1 and the second display area DA2 may be adjacent to each other in the first direction DR1, and an intermediate area CA may be disposed between the first display area DA1 and the second display area DA2. A first-side image IM1a is displayed in the first display area DA1, and a second-side image IM2a is displayed in the second display area DA2. The first display area DA1 may be an area located in front of the driver’s seat of the vehicle AM (refer to FIG. 1), and the second display area DA2 may be an area located in front of the front passenger seat of the vehicle AM.

In an embodiment of the present disclosure, the first display area DA1 and the second display area DA2 may be driven independently of each other. For example, the first display area DA1 may display an image in the first mode or the second mode, and the second display area DA2 may display an image in the first mode or the second mode. The first mode may be a normal mode, a public mode, or a wide viewing angle mode for displaying a screen at a first viewing angle, and the second mode may be a viewing angle control mode for displaying a screen at a second viewing angle narrower than the first viewing angle. The second mode may be referred to as a privacy mode, a privacy protection mode, or a narrow viewing angle mode. When one of the first display area DA1 and the second display area DA2 operates in the second mode, the driver DV may visually recognize an image only in the substantially front direction because the viewing range of the image is narrowed. In contrast, when one of the first display area DA1 and the second display area DA2 operates in the first mode, the viewing angle of an image is widened, and thus the driver DV may visually recognize the image even in the lateral direction.

As illustrated in FIGS. 3A and 4A, both the first display area DA1 and the second

display area DA2 may operate in the first mode. In the first mode, the driver DV of the vehicle AM may visually recognize not only the first-side image IM1a displayed in the first display area DA1 but also the second-side image IM2a displayed in the second display area DA2. In addition, in the first mode, a front seat passenger FP may visually recognize not only the second-side image IM2a displayed in the second display area DA2 but also the first-side image IM1a displayed in the first display area DA1.

However, as illustrated in FIG. 3B, the first display area DA1 may operate in the first mode, and the second display area DA2 may operate in the second mode. In this case, the driver DV may visually recognize the first-side image IM1a displayed in the first display area DA1 but may not visually recognize the second-side image IM2a displayed in the second display area DA2.

In an embodiment of the present disclosure, mode switching of the second display area DA2 (e.g., switching from the first mode to the second mode or switching from the second mode to the first mode) may be automatically performed depending on the travel speed of the vehicle AM. For example, when the travel speed of the vehicle AM is lower than or equal to a preset reference speed, the second display area DA2 may display an image in the first mode. However, when the travel speed of the vehicle AM exceeds the reference speed, the second display area DA2 may switch to the second mode. Accordingly, when the travel speed exceeds the reference speed, the driver DV is not able to visually recognize the second-side image IM2a displayed in the second display area DA2.

On the other hand, as illustrated in FIG. 4B, the first display area DA1 may operate in the second mode, and the second display area DA2 may operate in the first mode. In this case, the front seat passenger FP may visually recognize the second-side image IM2a displayed in the

second display area DA2 but may not visually recognize the first-side image IM1a displayed in the first display area DA1.

In an embodiment of the present disclosure, a mode switching method of the first display area DA1 and the second display area DA2 may be performed in various ways by the user’s operation (or, settings).

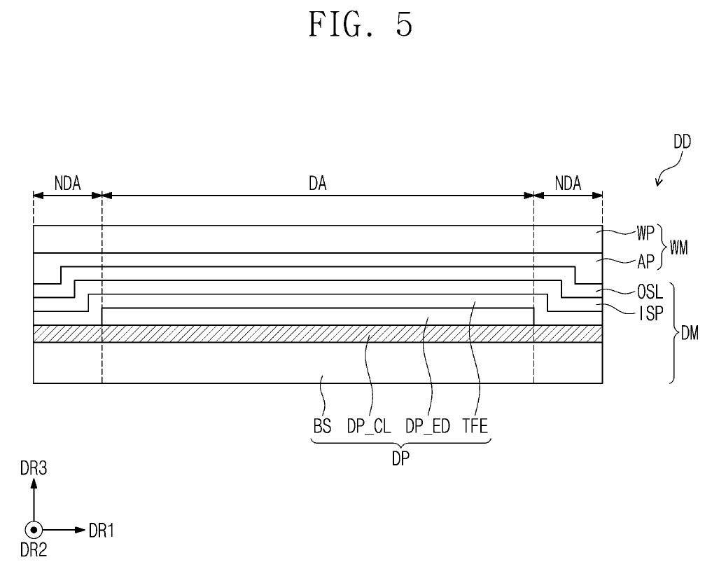

FIG. 5 is a sectional view of an electronic device according to an embodiment of the present disclosure.

Referring to FIG. 5, the electronic device DD may include a display module DM and a window member WM disposed on the display module DM. The display module DM may include a display panel DP, an input sensing layer ISP disposed on the display panel DP, and an optical path control layer OSL disposed on the input sensing layer ISP.

The display panel DP may be an emissive display panel. For example, the display panel DP may be an organic light emitting display panel, an inorganic light emitting display panel, a quantum-dot display panel, a micro LED display panel, or a nano LED display panel. The display panel DP may be referred to as a display layer. The display panel DP may include a base layer BS, a display circuit layer DP_CL, a display element layer DP_ED, and an encapsulation layer TFE.

The base layer BS may be a member that provides a base surface on which the display circuit layer DP_CL is disposed. The base layer BS may be a rigid substrate or may be a flexible substrate capable of being bent, folded, or rolled. The base layer BS may be a glass substrate, a metal substrate, or a polymer substrate. However, embodiments of the present disclosure are not limited thereto, and the base layer BS may be an inorganic base layer, an organic base layer, or a composite layer.

The display circuit layer DP_CL may be disposed on the base layer BS. The display circuit layer DP_CL may include a plurality of insulating layers, a plurality of conductive layers, and a semiconductor layer. The plurality of conductive layers of the display circuit layer DP_CL may constitute signal lines or a pixel circuit.

The display element layer DP_ED may be disposed on the display circuit layer DP_CL. The display element layer DP_ED may include light emitting elements. For example, the display element layer DP_ED may include organic light emitting diodes, inorganic light emitting diodes, quantum dots, quantum rods, micro-LEDs, or nano-LEDs.

The encapsulation layer TFE may be disposed on the display element layer DP_ED. The encapsulation layer TFE may protect the display element layer DP_ED from foreign matter such as moisture, oxygen, and dust particles.

The input sensing layer ISP may be disposed on the encapsulation layer TFE. The input sensing layer ISP may sense an external input, may change the external input into a certain input signal, and may provide the input signal to the display panel DP. For example, in the electronic device DD of an embodiment, the input sensing layer ISP may be a touch sensing unit that senses a touch. The input sensing layer ISP may recognize a direct touch of a user, an indirect touch of the user, a direct touch of an object, or an indirect touch of the object.

The input sensing layer ISP may sense at least one of the position of a touch applied from the outside or the intensity (pressure) of the touch. The display panel DP may receive an input signal from the input sensing layer ISP and may generate an image corresponding to the input signal. For example, the input sensing layer ISP may sense an external input in a capacitance type. However, this is illustrative, and a method of driving the input sensing layer ISP is not limited to any one embodiment.

The display panel DP and the input sensing layer ISP may be formed through a continuous process. That is, the input sensing layer ISP may be directly formed on the encapsulation layer TFE. A separate adhesive member may not be disposed between the input sensing layer ISP and the display panel DP. In an embodiment, the input sensing layer ISP may be coupled with the display panel DP through an adhesive member. The adhesive member may include a conventional adhesive or sticky substance.

In this specification, when a component is directly disposed/formed on another component, this means that a third component is not disposed therebetween. That is, when a component is “directly disposed/formed” on another component, this means that the component “makes contact with” the other component.

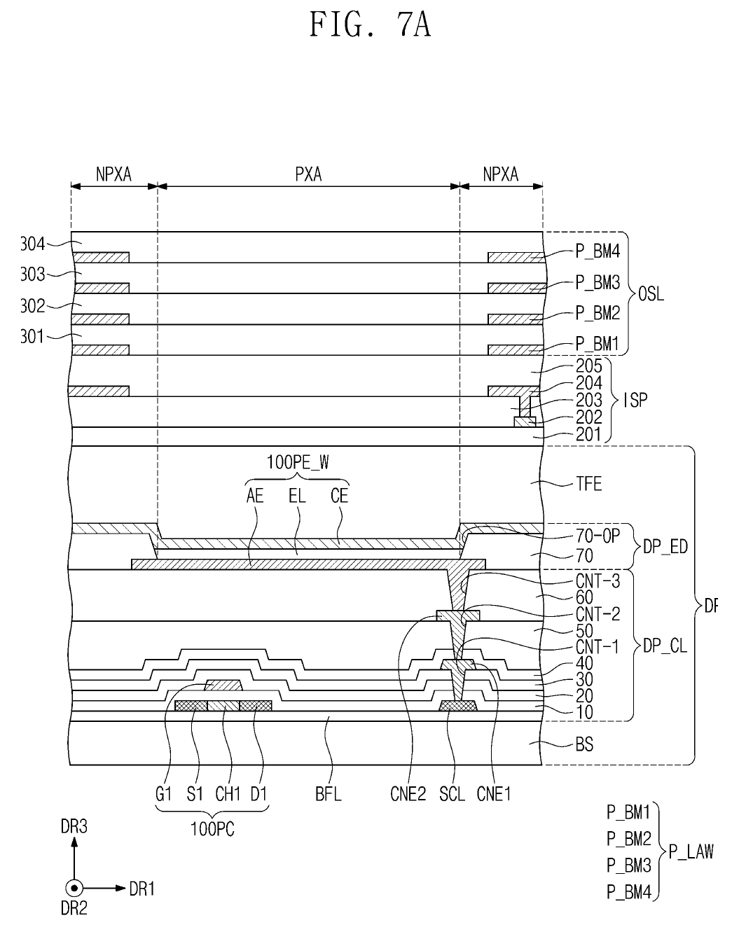

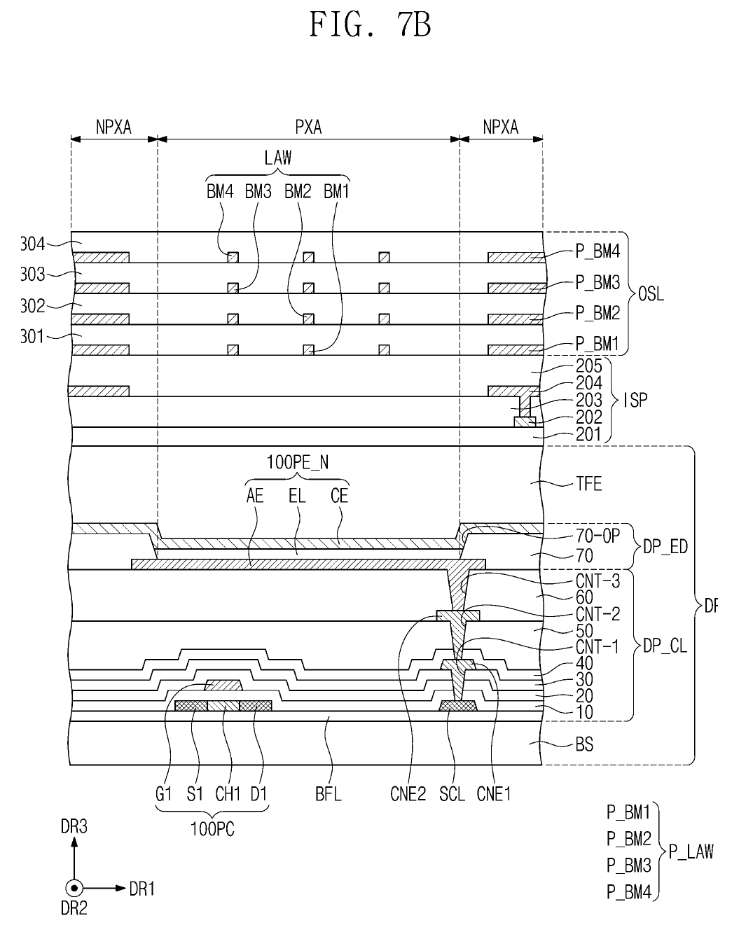

The optical path control layer OSL may be disposed on the input sensing layer ISP. The optical path control layer OSL may include a structure for controlling the path of light output from the display panel DP. The optical path control layer OSL may be formed with the display panel DP and the input sensing layer ISP through a continuous process and may be directly disposed on the input sensing layer ISP. However, the present disclosure is not particularly limited thereto. For example, the optical path control layer OSL may be coupled to the input sensing layer ISP through an adhesive layer. The configuration of the optical path control layer OSL will be described below in detail with reference to FIGS. 7A and 7B.

The window member WM may be disposed on the display module DM. The window member WM may include a window WP and an adhesive layer AP. The window member WM may further include at least one functional layer (not illustrated) that is provided on the window WP. For example, the functional layer (not illustrated) may be a hard coating layer or an anti-fingerprint coating layer. However, embodiments of the present disclosure are not limited thereto.

The window WP may include an optically clear insulating material. The window WP may be a glass substrate or a polymer substrate. For example, the window WP may be a tempered glass substrate. The adhesive layer AP may be disposed between the display module DM and the window WP. The window WP and a component adjacent to the window WP (e.g., the display module DM (or the optical path control layer OSL)) may be coupled by the adhesive layer AP. The adhesive layer AP may include a conventional adhesive, such as a pressure sensitive adhesive (PSA), an optically clear adhesive (OCA), or an optical clear resin (OCR), and is not limited to any one embodiment. For example, the adhesive layer AP may be omitted.

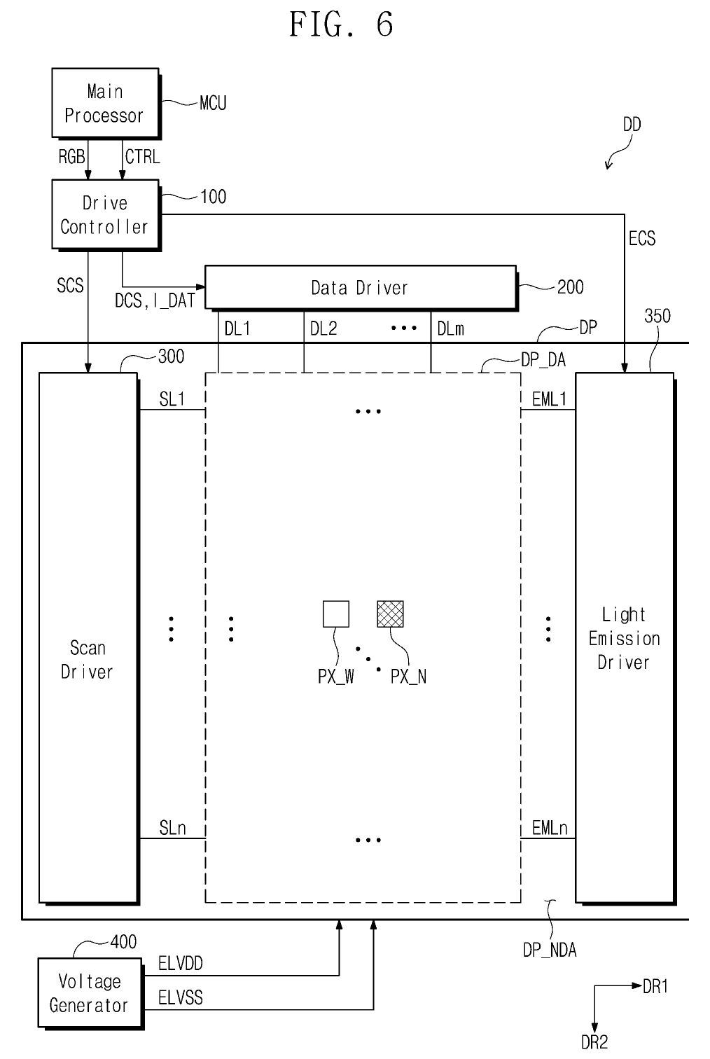

FIG. 6 is a block diagram of an electronic device according to an embodiment of the present disclosure.

Referring to FIG. 6, the electronic device DD may include a main processor MCU, a panel driver, and the display panel DP.

The main processor MCU may include at least one of a central processing unit (CPU) or an application processor (APU). The main processor MCU may further include at least one of a graphic processing unit (GPU), a communication processor (CP), or an image signal processor (ISP). Additionally, the main processor MCU may be one or more main processors. The one or more main processors may perform operations, individually, as a collective or as a selection within the collective, e.g., two main processors out of a collective of three main processors may perform an operation together.

The panel driver includes a drive controller 100, a data driver 200, a scan driver 300, a light emission driver 350, and a voltage generator 400. The panel driver may drive the display panel DP in a first mode or a second mode in response to a first mode enable signal or a second mode enable signal received from the main processor MCU.

The drive controller 100 receives an image signal RGB and a control signal CTRL from the main processor MCU. The drive controller 100 outputs image data I_DAT obtained by converting the data format of the image signal RGB according to the specification of an interface with the data driver 200. The drive controller 100 may output various drive control signals (e.g., first to third drive control signals DCS, SCS, and ECS) to drive the display panel DP, based on the control signal CTRL. The first mode enable signal and the second mode enable signal may be signals included in the control signal CTRL.

The display panel DP includes a display area DP_DA and a non-display area DP_NDA adjacent to the periphery of the display area DP_DA. The display area DP_DA may be an area corresponding to the display area DA illustrated in FIG. 1A, and the non-display area DP_NDA may be an area corresponding to the non-display area NDA illustrated in FIG. 1A. The display area DP_DA is an area on which an image is substantially displayed, and the non-display area DP_NDA is a bezel area on which an image is not displayed.

The display panel DP includes a plurality of pixels, a plurality of scan lines SL1 to SLn, a plurality of light emission control lines EML1 to EMLn, and a plurality of data lines DL1 to DLm. The scan lines SL1 to SLn and the light emission control lines EML1 to EMLn extend in the first direction DR1. The scan lines SL1 to SLn and the light emission control lines EML1 to EMLn are spaced apart from one another in the second direction DR2. The data lines DL1 to DLm extend in the second direction DR2 and are spaced apart from one another in the first direction DR1. Here, “n” and “m” are natural numbers of 1 or more.

The plurality of pixels are electrically connected to the scan lines SL1 to SLn, the light emission control lines EML1 to EMLn, and the data lines DL1 to DLm. For example, two or more scan lines may be electrically connected to each of the plurality of pixels. The plurality of pixels may include wide pixels PX_W (or, normal pixels) and narrow pixels PX_N (or, viewing angle control pixels). The wide pixels PX_W and the narrow pixels PX_N may alternate with one another in the first direction DR1 or the second direction DR2. The wide pixels PX_W and the narrow pixels PX_N may have substantially the same configuration. However, a structure (or, referred to as a light absorbing barrier wall LAW (refer to FIG. 7B)) capable of controlling a viewing angle may be additionally disposed over the narrow pixels PX_N.

The display panel DP displays an image at a first viewing angle using the wide pixels PX_W and the narrow pixels PX_N in the first mode and displays an image at a second viewing angle narrower than the first viewing angle using only the narrow pixels PX_N in the second mode. The light output range of an image output from the narrow pixels PX_N is narrowed by the light absorbing barrier wall LAW, and thus the viewing angle of the image displayed in the second mode may be adjusted.

The data driver 200 receives the image data I_DAT and the first drive control signal DCS from the drive controller 100. The data driver 200 may compensate for the image data I_DAT such that an image is displayed with desired luminance depending on the characteristics of the electronic device DD or a user’s settings or may convert the image data I_DAT to reduce power consumption or compensate for afterimages. The data driver 200 converts the image data I_DAT into data signals (e.g., an effective data signal or a non-effective data signal) and outputs the data signals to the plurality of data lines DL1 to DLm to be described below. The data signals are analog voltages corresponding to grayscale values of the image data I_DAT.

The scan driver 300 may be disposed in the non-display area DP_NDA of the display panel DP. The scan driver 300 receives the second drive control signal SCS from the drive controller 100. The scan driver 300 outputs scan signals to the scan lines SL1 to SLn in response to the second drive control signal SCS.

The light emission driver 350 may be disposed in the non-display area DP_NDA of the display panel DP. The light emission driver 350 receives the third drive control signal ECS from the drive controller 100. In response to the third drive control signal ECS, the light emission driver 350 may output light emission control signals to the light emission control lines EML1 to EMLn. In an embodiment, the scan driver 300 may be connected to the light emission control lines EML1 to EMLn. In this case, the light emission driver 350 may be omitted, and the scan driver 300 may output light emission control signals to the light emission control lines EML1 to EMLn.

The voltage generator 400 generates voltages for an operation of the display panel DP. In this embodiment, the voltage generator 400 generates a first drive voltage ELVDD and a second drive voltage ELVSS.

FIG. 7A is an enlarged sectional view illustrating a portion corresponding to a wide pixel of the electronic device illustrated in FIG. 6, and FIG. 7B is an enlarged sectional view illustrating a portion corresponding to a narrow pixel of the electronic device illustrated in FIG. 6.

Referring to FIGS. 7A and 7B, at least one inorganic layer may be formed on the upper surface of the base layer BS in the display panel DP. The inorganic layer may include at least one of aluminum oxide, titanium oxide, silicon oxide, silicon oxy nitride, silicon nitride, zirconium oxide, or hafnium oxide. The inorganic layer may be formed of multiple layers. The multiple inorganic layers may constitute a barrier layer and/or a buffer layer. In this embodiment, the display panel DP is illustrated as including a buffer layer BFL.

The buffer layer BFL may improve the coupling force between the base layer BS and a semiconductor pattern. The buffer layer BFL may include silicon oxide layers and silicon nitride layers, and the silicon oxide layers and the silicon nitride layers may be stacked one above another in alternating order.

The semiconductor pattern may be disposed on the buffer layer BFL. The semiconductor pattern may include poly silicon. However, without being limited thereto, the semiconductor pattern may include amorphous silicon, low temperature polycrystalline silicon, or oxide semiconductor.

FIGS. 7A and 7B illustrate only a portion of the semiconductor pattern, and the semiconductor pattern may be additionally disposed in other areas. The semiconductor pattern may be arranged across pixels according to a specific rule. The semiconductor pattern may have different electrical properties depending on whether doping is performed or not. The semiconductor pattern may include a first area having a high conductivity and a second area having a low conductivity. The first area may be doped with an N-type dopant or a P-type dopant. A P-type transistor may include a doped area doped with a P-type dopant, and an N-type transistor may include a doped area doped with an N-type dopant. The second area may be an undoped area or may be an area more lightly doped than the first area.

The first area may have a higher conductivity than the second area and may substantially serve as an electrode or a signal line. The second area may substantially correspond to a channel area of a transistor. In other words, one portion of the semiconductor pattern may be a channel of the transistor, another portion may be a source or drain of the transistor, and the other portion may be a connecting electrode or a connecting signal line.

Each of the pixels may have an equivalent circuit including a plurality of transistors, at least one capacitor, and a light emitting element, and the equivalent circuit of the pixel may be modified in various forms. In FIGS. 7A and 7B, one transistor 100PC and one light emitting element 100PE_W or 100PE_N included in the pixel are illustrated as an example.

The transistor 100PC may include a source S1, a channel area CH1, a drain D1, and a gate G1. The source S1, the channel area CH1, and the drain D1 may be formed from the semiconductor pattern. The source S1 and the drain D1 may extend from the channel area CH1 in opposite directions on the cross-sectional view. In FIG. 7A, a portion of a connecting signal line SCL formed from the semiconductor pattern is illustrated. Although not separately illustrated, the connecting signal line SCL may be electrically connected to the drain D1 of the transistor 100PC when viewed from above the plane.

A first insulating layer 10 may be disposed on the buffer layer BFL. The first insulating layer 10 may commonly overlap a plurality of pixels and may cover the semiconductor pattern. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy nitride, zirconium oxide, or hafnium oxide. In embodiments, the first insulating layer 10 may be a single silicon oxide layer. Not only the first insulating layer 10 but also insulating layers of the display circuit layer DP_CL to be described below may be inorganic layers and/or organic layers and may have a single-layer structure or a multi-layer structure. The inorganic layers may include at least one of the aforementioned materials but are not limited thereto.

The gate G1 is disposed on the first insulating layer 10. The gate G1 may be a portion of a metal pattern. The gate G1 overlaps the channel area CH1. The gate G1 may function as a mask in a process of doping the semiconductor pattern.

A second insulating layer 20 may be disposed on the first insulating layer 10 and may cover the gate G1. The second insulating layer 20 may commonly overlap the pixels. The second insulating layer 20 may be an inorganic layer and/or an organic layer and may have a single-layer structure or a multi-layer structure. The second insulating layer 20 may include at least one of silicon oxide, silicon nitride, or silicon oxy nitride. In this embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer structure or a multi-layer structure. For example, the third insulating layer 30 may have a multi-layer structure including a silicon oxide layer and a silicon nitride layer.

A first connecting electrode CNE1 may be disposed on the third insulating layer 30. The first connecting electrode CNE1 may be connected to the connecting signal line SCL through a contact hole CNT-1 that penetrates the first insulating layer 10, the second insulating layer 20, and the third insulating layer 30.

A fourth insulating layer 40 may be disposed on the third insulating layer 30 and may cover the first connecting electrode CNE1. The fourth insulating layer 40 may be a single silicon oxide layer. A fifth insulating layer 50 may be disposed on the fourth insulating layer 40. The fifth insulating layer 50 may be an organic layer.

A second connecting electrode CNE2 may be disposed on the fifth insulating layer 50. The second connecting electrode CNE2 may be connected to the first connecting electrode CNE1 through a contact hole CNT-2 that penetrates the fourth insulating layer 40 and the fifth insulating layer 50.

A sixth insulating layer 60 may be disposed on the fifth insulating layer 50 and may cover the second connecting electrode CNE2. The sixth insulating layer 60 may be an organic layer.

The display element layer DP_ED may be disposed on the display circuit layer DP_CL. The display element layer DP_ED may include light emitting elements 100PE_W and 100PE_N and a pixel defining layer 70. For example, the display element layer DP_ED may include an organic luminescent material, an inorganic luminescent material, a quantum dot, a quantum rod, a micro-LED, or a nano-LED. Hereinafter, it will be exemplified that the light emitting elements 100PE_W and 100PE_N are organic light emitting elements. However, the present disclosure is not particularly limited thereto.

Each of the light emitting elements 100PE_W and 100PE_N may include a first electrode AE, an emissive layer EL, and a second electrode CE. The first electrode AE may be disposed on the sixth insulating layer 60. The first electrode AE may be connected to the second connecting electrode CNE2 through a contact hole CNT-3 that penetrates the sixth insulating layer 60. The first electrode AE may be referred to as an anode.

The pixel defining layer 70 may be disposed on the sixth insulating layer 60 and may cover a portion of the first electrode AE. The pixel defining layer 70 has an opening 70-OP defined therein. The opening 70-OP of the pixel defining layer 70 exposes at least a portion of the first electrode AE.

The display area DP_DA (refer to FIG. 6) may include an emissive area PXA and a non-emissive area NPXA adjacent to the emissive area PXA. The non-emissive area NPXA may surround the emissive area PXA. In this embodiment, the emissive area PXA is defined to correspond to a partial area of the first electrode AE exposed through the opening 70-OP.

The emissive layer EL may be disposed on the first electrode AE. The emissive layer EL may be disposed in an area corresponding to the opening 70-OP. That is, the emissive layer EL may be separately formed in each of the pixels. When the emissive layer EL is separately formed in each of the pixels, each of the emissive layers EL may emit at least one of blue light, red light, or green light. However, without being limited thereto, the emissive layer EL may be connected to the pixels and may be provided in common. In this case, the emissive layer EL may provide blue light or white light. As used herein the term “green light” may refer to electromagnetic radiation in the band of wave-lengths typically considered to be the green light band. Similarly, “red light” may refer to electromagnetic radiation in the band of wave-lengths typically considered to be the red light band and “blue light” may refer to electromagnetic radiation in the band of wave-lengths typically considered to be the blue light band. The term “white light” may refer to electromagnetic radiation in a selection of wavelengths which appear white when viewed and, in an implementation, may include electromagnetic radiation in a broad selection of wavelengths across the visible electromagnetic radiation spectrum.

The second electrode CE may be disposed on the emissive layer EL. The second electrode CE may have a one-body shape and may be commonly disposed in the plurality of pixels. The second electrode CE may be referred to as a cathode.

Although not illustrated, a hole control layer may be disposed between the first electrode AE and the emissive layer EL. The hole control layer may be commonly disposed in the emissive area PXA and the non-emissive area NPXA. The hole control layer may include a hole transport layer and may further include a hole injection layer. An electron control layer may be disposed between the emissive layer EL and the second electrode CE. The electron control layer may include an electron transport layer and may further include an electron injection layer. The hole control layer and the electron control layer may be commonly formed in the plurality of pixels using an open mask.

The encapsulation layer TFE may be disposed on the display element layer DP_ED. The encapsulation layer TFE may include an inorganic layer, an organic layer, and an inorganic layer sequentially stacked one above another. However, layers constituting the encapsulation layer TFE are not limited thereto.

The inorganic layers may protect the display element layer DP_ED from moisture and oxygen, and the organic layer may protect the display element layer DP_ED from foreign matter such as dust particles. The inorganic layers may include a silicon nitride layer, a silicon oxy nitride layer, a silicon oxide layer, a titanium oxide layer, or an aluminum oxide layer. The organic layer may include an acrylic organic layer but is not limited thereto.

The input sensing layer ISP may be formed on the display panel DP through a continuous process. The input sensing layer ISP may include a base insulating layer 201, a first conductive layer 202, an intermediate insulating layer 203, a second conductive layer 204, and a cover insulating layer 205.

The base insulating layer 201 may be an inorganic layer including at least one of silicon nitride, silicon oxy nitride, or silicon oxide. In an embodiment, the base insulating layer 201 may be an organic layer including an epoxy-based resin, an acrylic-based resin, or an imide-based resin. The base insulating layer 201 may have a single-layer structure or may have a multi-layer structure stacked in the third direction DR3.

Each of the first conductive layer 202 and the second conductive layer 204 may have a single-layer structure or may have a multi-layer structure stacked in the third direction DR3.

A conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide, indium zinc oxide, zinc oxide, or indium zinc tin oxide. In addition, the transparent conductive layer may include a conductive polymer such as PEDOT, a metal nano-wire, or graphene.

A conductive layer having a multi-layer structure may include metal layers. The meal layers may have, for example, a three-layer structure of titanium/aluminum/titanium. The conductive layer having the multi-layer structure may include at least one metal layer and at least one transparent conductive layer.

At least one of the intermediate insulating layer 203 or the cover insulating layer 205 may include an inorganic film. The inorganic film may include at least one of aluminum oxide, titanium oxide, silicon oxide, silicon nitride, silicon oxy nitride, zirconium oxide, or hafnium oxide.

At least one of the intermediate insulating layer 203 or the cover insulating layer 205 may include an organic film. The organic film may include at least one of an acrylic-based resin, a methacrylic-based resin, a polyisoprene-based resin, a vinyl-based resin, an epoxy-based resin, a urethane-based resin, a cellulosic-based resin, a siloxane-based resin, a polyimide-based resin, a polyamide-based resin, or a perylene-based resin.

The optical path control layer OSL may be disposed on the cover insulating layer 205. The optical path control layer OSL may include a plurality of light absorbing barrier walls LAW disposed to correspond to the emissive area PXA and a peripheral barrier wall P_LAW disposed to correspond to the non-emissive area NPXA. The plurality of light absorbing barrier walls LAW may not be provided over the light emitting element 100PE_W of the wide pixel PX_W (refer to FIG. 6) (hereinafter, referred to as the wide light emitting element) and may be provided only over the light emitting element 100PE_N of the narrow pixel PX_N (refer to FIG. 6) (hereinafter, referred to as the narrow light emitting element). The plurality of light absorbing barrier walls LAW may overlap the narrow light emitting element 100PE_N when viewed from above the plane.

In an embodiment of the present disclosure, each of the plurality of light absorbing barrier walls LAW may include a plurality of black matrixes. Although FIG. 7B illustrates the structure in which each of the plurality of light absorbing barrier walls LAW includes four black matrixes (hereinafter, referred to as first to fourth black matrixes BM1, BM2, BM3, and BM4), the structure of each of the plurality of light absorbing barrier walls LAW is not limited thereto. For example, each of the plurality of light absorbing barrier walls LAW may include one black matrix or may include two or three black matrixes.

The first black matrix BM1 may be disposed on the cover insulating layer 205 and may be covered by a first transparent insulating layer 301. The second black matrix BM2 may be disposed on the first transparent insulating layer 301 and may be covered by a second transparent insulating layer 302. The third black matrix BM3 may be disposed on the second transparent insulating layer 302 and may be covered by a third transparent insulating layer 303. The fourth black matrix BM4 may be disposed on the third transparent insulating layer 303 and may be covered by a fourth transparent insulating layer 304. The first to fourth black matrixes BM1, BM2, BM3, and BM4 may be sequentially stacked in the third direction DR3 and may be aligned in the third direction DR3.

Each of the first to fourth black matrixes BM1, BM2, BM3, and BM4 may include a light absorbing material or a light blocking material. Accordingly, light incident to the first to fourth black matrixes BM1, BM2, BM3, and BM4 may be absorbed without being reflected. Each of the first to fourth transparent insulating layers 301, 302, 303, and 304 may include a transparent organic material.

The light output range of light output from the narrow light emitting element 100PE_N may be controlled by the plurality of light absorbing barrier walls LAW. That is, side light of the light output from the narrow light emitting element 100PE_N is absorbed by the light absorbing barrier walls LAW and is not output to the outside. The light output range of the light output from the narrow light emitting element 100PE_N may be narrowed by the light absorbing barrier walls LAW, and thus the viewing angle of an image displayed in the display area DA (refer to FIG. 1A) in the second mode may be narrowed (or, adjusted).

The peripheral barrier wall P_LAW may have a structure including a plurality of peripheral black matrixes P_BM1, P_BM2, P_BM3, and P_BM4. The plurality of peripheral black matrixes P_BM1, P_BM2, P_BM3, and P_BM4 may include first to fourth peripheral black matrixes P_BM1, P_BM2, P_BM3, and P_BM4 disposed on the same layers as the first to fourth black matrixes BM1, BM2, BM3, and BM4, respectively. The first to fourth peripheral black matrixes P_BM1, P_BM2, P_BM3, and P_BM4 may be sequentially stacked in the third direction DR3 and may be aligned in the third direction DR3. In an embodiment, the peripheral barrier wall P_LAW may be omitted from the optical path control layer OSL.

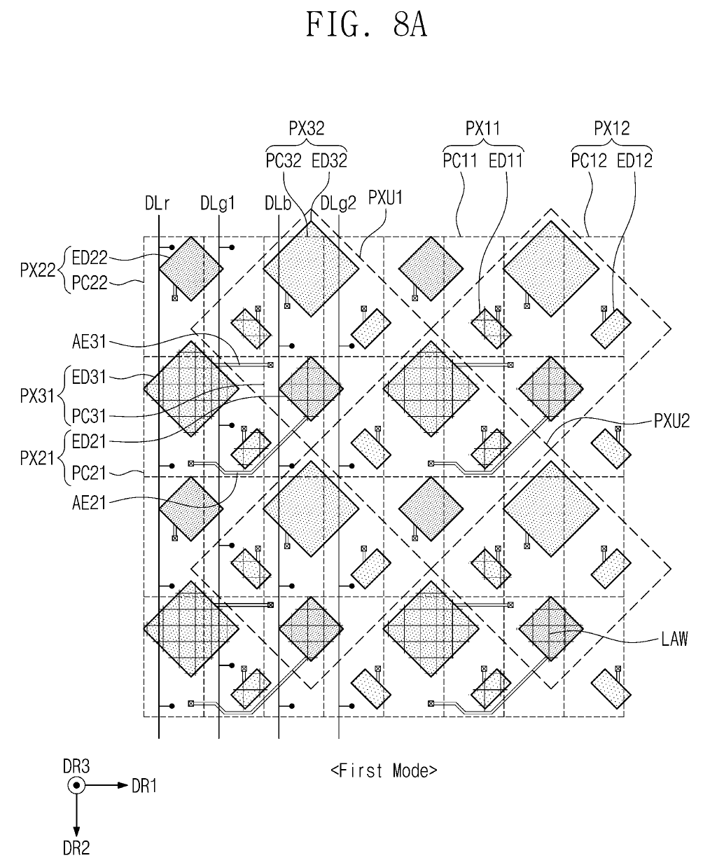

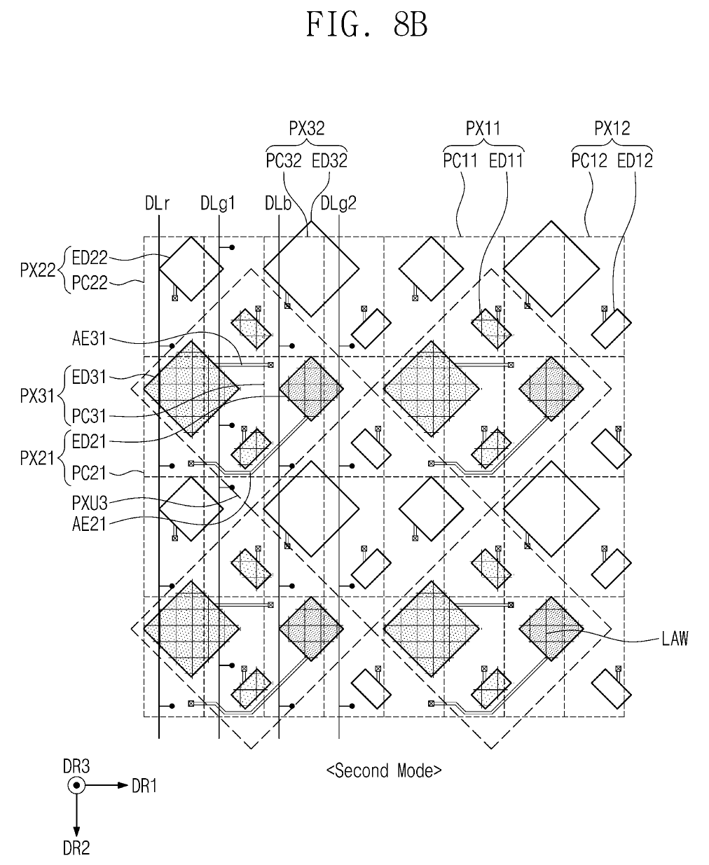

FIG. 8A is a view illustrating the display panel operating in the first mode according to an embodiment of the present disclosure. FIG. 8B is a view illustrating the display panel operating in the second mode according to an embodiment of the present disclosure.

Referring to FIGS. 8A and 8B, a plurality of pixels may include first-first type pixels PX11, first-second type pixels PX12, second-first type pixels PX21, second-second type pixels PX22, third-first type pixels PX31, and third-second type pixels PX32. The first-first type pixels PX11, the second-first type pixels PX21, and the third-first type pixels PX31 may belong to the narrow pixels PX_N (refer to FIG. 6), and the first-second type pixels PX12, the second-second type pixels PX22, and the third-second type pixels PX32 may belong to the wide pixels PX_W (refer to FIG. 6).

The first-first type pixels PX11 and the first-second type pixels PX12 output light of a first color (e.g., green light), and the second-first type pixels PX21 and the second-second type pixels PX22 output light of a second color (e.g., red light) that is different from the light of the first color. The third-first type pixels PX31 and the third-second type pixels PX32 output light of a third color (e.g., blue light) that is different from the light of the first color and the light of the second color.

The first-first type pixels PX11 are connected to a first-first type data line DLg1, and the first-second type pixels PX12 are connected to a first-second type data line DLg2. The second-first type pixels PX21 and the second-second type pixels PX22 are connected to a second type data line DLr, and the third-first type pixels PX31 and the third-second type pixels PX32 are connected to a third type data line DLb. The second type data line DLr, the first-first type data line DLg1, the third type data line DLb, and the first-second type data line DLg2 extend in the second direction DR2 and are spaced apart from one another in the first direction DR1. The second type data line DLr, the first-first type data line DLg1, the third type data line DLb, and the first-second type data line DLg2 may be sequentially disposed in the first direction DR1. The second type data line DLr, the first-first type data line DLg1, the third type data line DLb, and the first-second type data line DLg2 are components included in the data lines DL1 to DLm illustrated in FIG. 6.

Each of the first-first type pixels PX11 includes a first-first pixel circuit PC11 and a first-first light emitting element ED11 connected to the first-first pixel circuit PC11, and each of the first-second type pixels PX12 includes a first-second pixel circuit PC12 and a first-second light emitting element ED12 connected to the first-second pixel circuit PC12. The first-first pixel circuit

PC11 may overlap the first-first light emitting element ED11 when viewed from above the plane, and the first-second pixel circuit PC12 may overlap the first-second light emitting element ED12 when viewed from above the plane. The first-first light emitting element ED11 and the first-second light emitting element ED12 may be spaced apart from each other in the first direction DR1. The first-first pixel circuits PC11 and the first-first light emitting elements ED11 of the first-first type pixels PX11 are arranged in the second direction DR2, and the first-second pixel circuits PC12 and the first-second light emitting elements ED12 of the first-second type pixels PX12 are arranged in the second direction DR2. The first-first pixel circuits PC11 are connected to the first-first type data line DLg1, and the first-second pixel circuits PC12 are connected to the first-second type data line DLg2.

Each of the second-first type pixels PX21 includes a second-first pixel circuit PC21 and a second-first light emitting element ED21 connected to the second-first pixel circuit PC21, and each of the second-second type pixels PX22 includes a second-second pixel circuit PC22 and a second-second light emitting element ED22 connected to the second-second pixel circuit PC22. The second-first pixel circuit PC21 and the second-second pixel circuit PC22 are disposed in the second direction DR2 in alternating order. The second-first pixel circuit PC21 and the second-second pixel circuit PC22 are connected to the second type data line DLr. The second-first light emitting elements ED21 of the second-first type pixels PX21 are disposed in the third column, and the second-second light emitting elements ED22 of the second-second type pixels PX22 are disposed in the first column. The second-second pixel circuit PC22 may overlap the second-second light emitting element ED22 when viewed from above the plane, but the second-first pixel circuit PC21 may not overlap the second-first light emitting element ED21 when viewed from above the plane. Accordingly, an anode AE21 of the second-first light emitting element ED21 may extend

toward the second-first pixel circuit PC21. In an embodiment of the present disclosure, when the second-first pixel circuit PC21 is disposed on the left side with respect to the second-first light emitting element ED21, the anode AE21 of the second-first light emitting element ED21 may extend in the left direction. In an embodiment, each of the second-first type pixels PX21 may further include a bridge electrode that connects the second-first light emitting element ED21 and the second-first pixel circuit PC21. The bridge electrode may be disposed in the same layer as the anode AE21 and may be integrally formed with the anode AE21. In an example, the bridge electrode may be disposed in a layer different from the layer in which the anode AE21 is disposed.

Each of the third-first type pixels PX31 includes a third-first pixel circuit PC31 and a third-first light emitting element ED31 connected to the third-first pixel circuit PC31, and each of the third-second type pixels PX32 includes a third-second pixel circuit PC32 and a third-second light emitting element ED32 connected to the third-second pixel circuit PC32. The third-first pixel circuit PC31 and the third-second pixel circuit PC32 are disposed in the second direction DR2 in alternating order. The third-first pixel circuit PC31 and the third-second pixel circuit PC32 are connected to the third type data line DLb. The third-first light emitting elements ED31 of the third-first type pixels PX31 are disposed in the first column, and the third-second light emitting elements ED32 of the third-second type pixels PX32 are disposed in the third column. The third-second pixel circuit PC32 may overlap the third-second light emitting element ED32 when viewed from above the plane, but the third-first pixel circuit PC31 may not overlap the third-first light emitting element ED31 when viewed from above the plane. Accordingly, an anode AE31 of the third-first light emitting element ED31 may extend toward the third-first pixel circuit PC31. In an embodiment of the present disclosure, when the third-first pixel circuit PC31 is disposed on the right side with respect to the third-first light emitting element ED31, the anode AE31 of the third-

first light emitting element ED31 may extend in the right direction. In an embodiment, each of the third-first type pixels PX31 may further include a bridge electrode that connects the third-first light emitting element ED31 and the third-first pixel circuit PC31. The bridge electrode may be disposed in the same layer as the anode AE31 and may be integrally formed with the anode AE31. In an example, the bridge electrode may be disposed in a layer different from the layer in which the anode AE31 is disposed.

In an embodiment of the present disclosure, the second-second light emitting elements ED22 and the third-second light emitting elements ED32 are disposed in the first row, and the first-first light emitting elements ED11 and the first-second light emitting elements ED12 are disposed in the second row. The third-first light emitting elements ED31 and the second-first light emitting elements ED21 are disposed in the third row, and the first-first light emitting elements ED11 and the first-second light emitting elements ED12 are disposed in the fourth row. The second-second light emitting elements ED22 and the third-second light emitting elements ED32 alternate with one another in the first row, the first-first light emitting elements ED11 and the first-second light emitting elements ED12 alternate with one another in the first direction DR1 in the second row and the fourth row, and the third-first light emitting elements ED31 and the second-first light emitting elements ED21 alternate with one another in the first direction DR1 in the third row. The first to fourth rows may be parallel to the first direction DR1, and the arrangement of the first to fourth rows may be repeated in the second direction DR2.

The second-second light emitting elements ED22 and the third-first light emitting elements ED31 are disposed in the first column. The first-first light emitting elements ED11 are disposed in the second column. The third-second light emitting elements ED32 and the second-first light emitting elements ED21 are disposed in the third column. The first-second light emitting elements ED12 are disposed in the fourth column. The second-second light emitting elements ED22 and the third-first light emitting elements ED31 alternate with one another in the first column, and the third-second light emitting elements ED32 and the second-first light emitting elements ED21 alternate with one another in the third row. The first-first light emitting elements ED11 are arranged in the second direction DR2 along the first-first type data line DLg1, and the first-second light emitting elements ED12 are arranged in the second direction DR2 along the first-second type data line DLg2.

Referring to FIGS. 8A and 8B, in the first mode, the display panel DP operates using a first pixel unit PXU1 and a second pixel unit PXU2. The first pixel unit PXU1 includes the first-first type pixel PX11, the first-second type pixel PX12, the second-first type pixel PX21, and the third-second type pixel PX32, and the second pixel unit PXU2 includes the first-first type pixel PX11, the first-second type pixel PX12, the second-second type pixel PX22, and the third-first type pixel PX31. In the first mode, the drive controller 100 may process (or, render) the image signal RGB to appropriately drive the first pixel unit PXU1 and the second pixel unit PXU2.

In the second mode, the display panel DP operates using a third pixel unit PXU3 having a configuration different from those of the first pixel unit PXU1 and the second pixel unit PXU2. The third pixel unit PXU3 includes two first-first type pixels PX11, the second-first type pixel PX21, and the third-first type pixel PX31. In the second mode, the drive controller 100 may process (or, render) the image signal RGB to appropriately drive the third pixel unit PXU3.

The light absorbing barrier walls LAW are disposed over the first-first light emitting element ED11, the second-first light emitting element ED21, and the third-first light emitting element ED31. The light absorbing barrier walls LAW are not disposed over the first-second light emitting element ED12, the second-second light emitting element ED22, and the third-second light emitting element ED32. The light absorbing barrier walls LAW may overlap the first-first light emitting element ED11, the second-first light emitting element ED21, and the third-first light emitting element ED31 when viewed from above the plane. In an embodiment of the present disclosure, the light absorbing barrier walls LAW may have a mesh structure when viewed from above the plane. Accordingly, when the display panel DP displays an image using only the first-first type pixel PX11, the second-first type pixel PX21, and the third-first type pixel PX31 in the second mode, the display panel DP may display the image at a viewing angle narrower than that in the first mode.

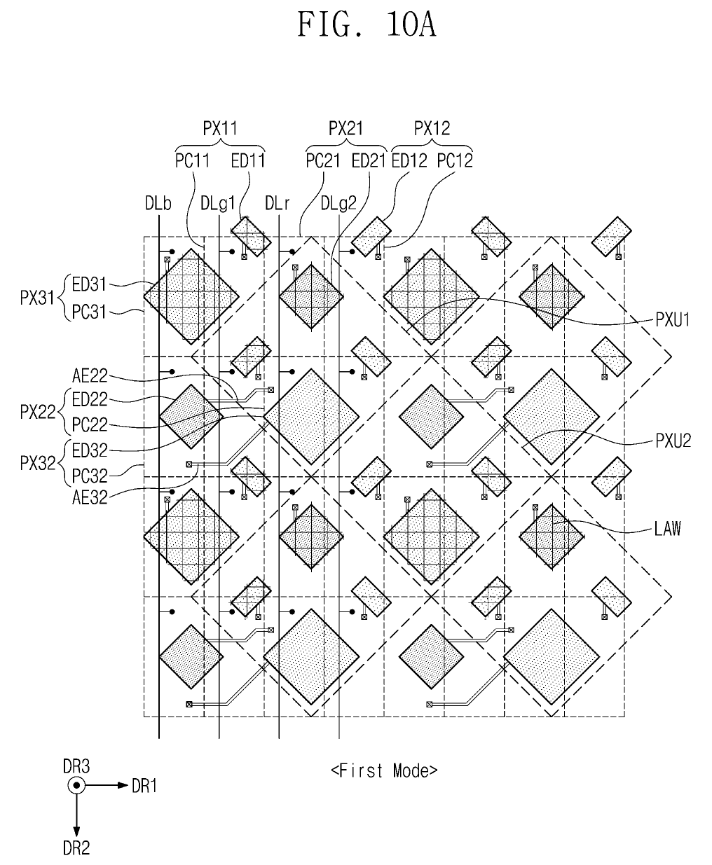

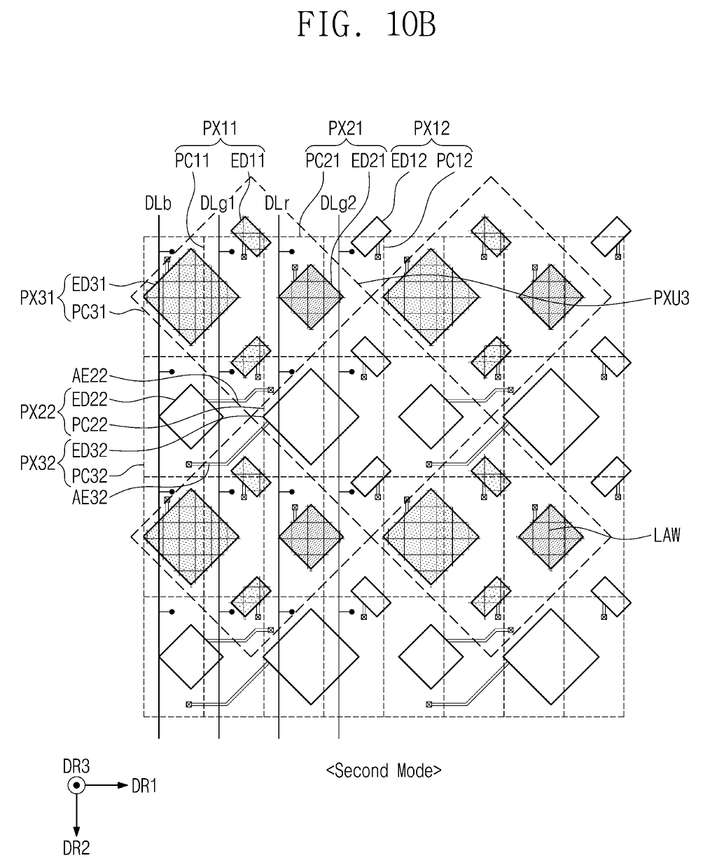

Although FIGS. 8A and 8B illustrate the structure in which the anodes AE21 and AE31 of the light emitting elements ED21 and ED31 of the second-first type pixels PX21 and the third-first type pixels PX31 belonging to the narrow pixels PX_N extend, the present disclosure is not limited thereto. For example, as illustrated in FIGS. 10A and 10B, the anodes of the light emitting elements ED22 and ED32 of the second-second type pixels PX22 and the third-second type pixels PX32 belonging to the wide pixels PX_W may extend.

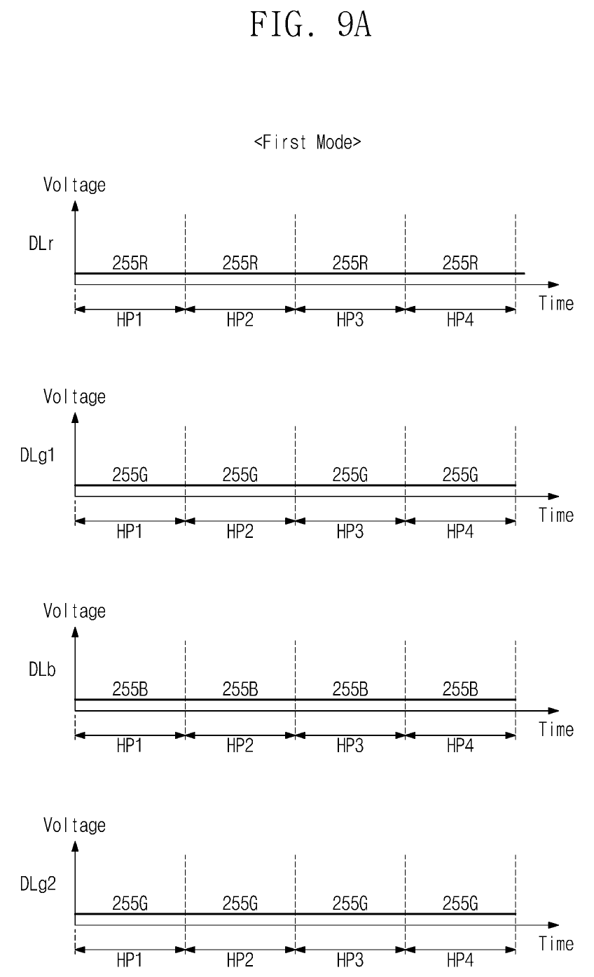

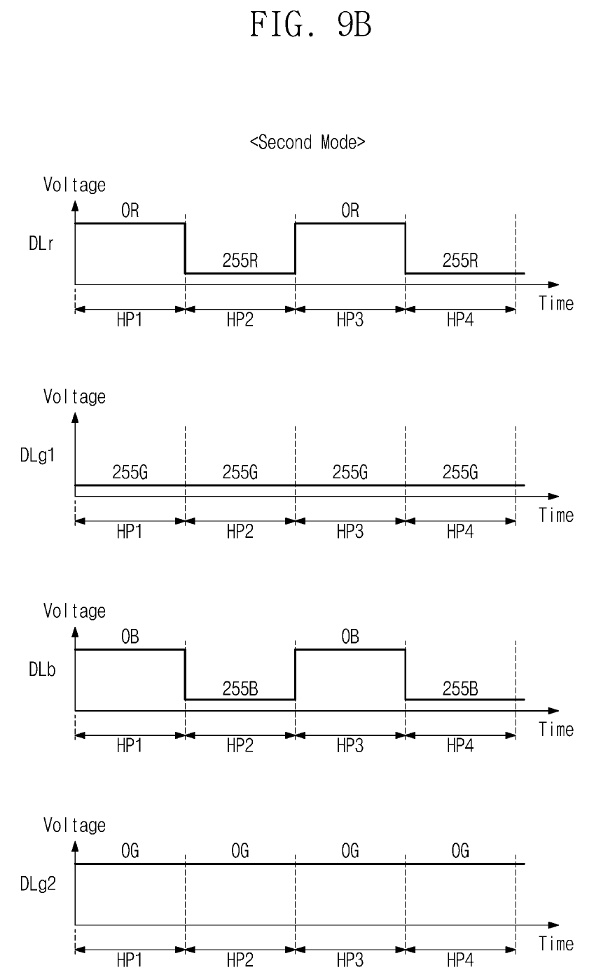

FIG. 9A illustrates waveform diagrams of data signals applied to the first-first type data line, the first-second type data line, the second type data line, and the third type data line in the first mode according to an embodiment of the present disclosure. FIG. 9B illustrates waveform diagrams of data signals applied to the first-first type data line, the first-second type data line, the second type data line, and the third type data line in the second mode according to an embodiment of the present disclosure.

Referring to FIGS. 8A and 9A, in the first mode, the display panel DP displays an image using all pixels (that is, the wide pixels PX_W and the narrow pixels PX_N (refer to FIG. 6)). Accordingly, in the first mode, the first-first type data line DLg1, the second type data line

DLr, the first-second type data line DLg2, and the third type data line DLb receive a first-first effective data signal, a second effective data signal, a first-second effective data signal, and a third effective data signal, respectively. In the first mode, the first-first type pixels PX11 and the first-second type pixels PX12 may output light of the first color having a grayscale value corresponding to the first-first effective data signal and the first-second effective data signal, and the first-second type pixels PX12 may output light of the first color having a grayscale value corresponding to the first-second effective data signal. In the first mode, the second-first type pixels PX21 and the second-second type pixels PX22 may output light of the second color having a grayscale value corresponding to the second effective data signal, and the third-first type pixels PX31 and the third-second type pixels PX32 may output light of the third color having a grayscale value corresponding to the third effective data signal.

In an embodiment of the present disclosure, the first-first effective data signal may be a green data signal having one of the grayscale values from 0 to 255. Here, the grayscale value “0” may be a black grayscale, and the grayscale value “255” may be a white grayscale. When the first pixel unit PXU1 and the second pixel unit PXU2 display a white image in the first mode, the first-first type data line DLg1 may receive a green data signal 255G having the grayscale value “255” as the first-first effective data signal during first to fourth horizontal scan periods HP1 to HP4.

The first-second effective data signal may be a green data signal having one of the grayscale values from 0 to 255. When the first pixel unit PXU1 and the second pixel unit PXU2 display a white image in the first mode, the first-second type data line DLg2 may receive a green data signal 255G having the grayscale value “255” as the first-second effective data signal during the first to fourth horizontal scan periods HP1 to HP4.

The second effective data signal may be a red data signal having one of the grayscale values from 0 to 255. When the first pixel unit PXU1 and the second pixel unit PXU2 display a white image in the first mode, the second type data line DLr may receive a red data signal 255R having the grayscale value “255” as the second effective data signal during the first to fourth horizontal scan periods HP1 to HP4.

The third effective data signal may be a blue data signal having one of the grayscale values from 0 to 255. When the first pixel unit PXU1 and the second pixel unit PXU2 display a white image in the first mode, the third type data line DLb may receive a blue data signal 255B having the grayscale value “255” as the third effective data signal during the first to fourth horizontal scan periods HP1 to HP4.

As the image displayed by the first pixel unit PXU1 and the second pixel unit PXU2 varies, the grayscale values of the first-first effective data signal, the first-second effective data signal, the second effective data signal, and the third effective data signal may vary.

The second type data line DLr receives the red data signal 255R including red color information, and the third type data line DLb receives the blue data signal 255B including blue color information. That is, since the color information of the data signals applied to the second type data line DLr and the third type data line DLb does not change with time, power consumption may be reduced. Likewise, since the color information of the data signals applied to the first-first type data line DLg1 and the first-second type data line DLg2 does not change with time, power consumption may be reduced.

Referring to FIGS. 8B and 9B, in the second mode, the display panel DP displays an image using only the narrow pixels PX_N. In the second mode, the wide pixels PX_W are not used to display the image. Accordingly, in the second mode, the first-first type data line DLg1 receives the first-first effective data signal, and the second type data line DLr receives the second effective data signal and a non-effective data signal in alternating order. In addition, in the second mode, the first-second type data line DLg2 receives a non-effective data signal, and the third type data line DLb receives the third effective data signal and a non-effective data signal in alternating order.

In the second mode, the first-first type pixels PX11 output light of the first color having a grayscale value corresponding to the first-first effective data signal, the second-first type pixels PX21 output light of the second color having a grayscale value corresponding to the second effective data signal, and the third-first type pixels PX31 output light of the third color having a grayscale value corresponding to the third effective data signal. In the second mode, the first-second type pixels PX12, the second-second type pixels PX22, and the third-second type pixels PX32 receive a non-effective data signal and therefore substantially display a black image or a non-effective image. That is, in the second mode, the narrow pixels PX_N may receive effective data signals and therefore may display an image, but the wide pixels PX_W may receive a non-effective data signal and therefore may display a black image or a non-effective image.

When the third pixel unit PXU3 displays a white image in the second mode, the first-first type data line DLg1 may receive a green data signal 255G having the grayscale value “255” as the first-first effective data signal during the first to fourth horizontal scan periods HP1 to HP4. In the second mode, the first-second type data line DLg2 may receive a green data signal 0G having the grayscale value “0” as a non-effective data signal. That is, the non-effective data signal may have a voltage level corresponding to the black grayscale.

In the second mode, the data signal applied to the first-first type data line DLg1 may be maintained as the first-first effective data signal, and the data signal applied to the first- second type data line DLg2 may be maintained as the non-effective data signal. Accordingly, in the second mode, a swing operation between an effective data signal and a non-effective data signal may be minimized, and thus power consumption may be reduced.

When the third pixel unit PXU3 displays a white image in the second mode, the second type data line DLr may receive a red data signal 0R having the grayscale value “0” as a non-effective data signal during the first horizontal scan period HP1 and the third horizontal scan period HP3. The second type data line DLr may receive a red data signal 255R having the grayscale value “255” as the second effective data signal during the second horizontal scan period HP2 and the fourth horizontal scan period HP4.

When the third pixel unit PXU3 displays a white image in the second mode, the third type data line DLb may receive a blue data signal 0B having the grayscale value “0” as a non-effective data signal during the first horizontal scan period HP1 and the third horizontal scan period HP3. The third type data line DLb may receive a blue data signal 255B having the grayscale value “255” as the third effective data signal during the second horizontal scan period HP2 and the fourth horizontal scan period HP4.

Although the data signals applied the second type data line DLr and the third type data line DLb swing between the effective data signal and the non-effective data signal, the data signals applied to the first-first type data line DLg1 and the first-second type data line DLg2 are fixed as the effective data signal or the non-effective data signal, and a swing operation does not occur. Thus, overall power consumption may be reduced.

Although FIGS. 9A and FIG. 9B illustrate the case of expressing 256 grayscale values, the grayscale range expressed by each data signal may be modified in various ways. In addition, although FIGS. 9A and 9B illustrate an example that the non-effective data signal has a voltage level corresponding to the black grayscale (that is, the grayscale value “0”), the present disclosure is not limited thereto.

FIG. 10A is a view illustrating the display panel operating in the first mode according to an embodiment of the present disclosure. FIG. 10B is a view illustrating the display panel operating in the second mode according to an embodiment of the present disclosure.

Referring to FIGS. 10A and 10B, first-first type pixels PX11 are connected to a first-first type data line DLg1, and first-second type pixels PX12 are connected to a first-second type data line DLg2. The second-first type pixels PX21 and second-second type pixels PX22 are connected to a second type data line DLr, and third-first type pixels PX31 and third-second type pixels PX32 are connected to a third type data line DLb. The third type data line DLb, the first-first type data line DLg1, the second type data line DLr, and the first-second type data line DLg2 may be sequentially disposed in the first direction DR1.

Each of the first-first type pixels PX11 includes a first-first pixel circuit PC11 and a first-first light emitting element ED11 connected to the first-first pixel circuit PC11, and each of the first-second type pixels PX12 includes a first-second pixel circuit PC12 and a first-second light emitting element ED12 connected to the first-second pixel circuit PC12. The first-first pixel circuits PC11 and the first-first light emitting elements ED11 of the first-first type pixels PX11 are arranged in the second direction DR2 along the first-first type data line DLg1. The first-second pixel circuits PC12 and the first-second light emitting elements ED12 of the first-second type pixels PX12 are arranged in the second direction DR2 along the first-second type data line DLg2. The first-first pixel circuits PC11 are connected to the first-first type data line DLg1, and the first-second pixel circuits PC12 are connected to the first-second type data line DLg2.

Each of the second-first type pixels PX21 includes a second-first pixel circuit PC21 and a second-first light emitting element ED21 connected to the second-first pixel circuit PC21, and each of the second-second type pixels PX22 includes a second-second pixel circuit PC22 and a second-second light emitting element ED22 connected to the second-second pixel circuit PC22. The second-first pixel circuit PC21 and the second-second pixel circuit PC22 are disposed in the second direction DR2 in alternating order. The second-first pixel circuit PC21 and the second-second pixel circuit PC22 are connected to the second type data line DLr. The second-first light emitting elements ED21 of the second-first type pixels PX21 are disposed in the third column, and the second-second light emitting elements ED22 of the second-second type pixels PX22 are disposed in the first column. The second-first pixel circuit PC21 may overlap the second-first light emitting element ED21 when viewed from above the plane, but the second-second pixel circuit PC22 may not overlap the second-second light emitting element ED22 when viewed from above the plane. Accordingly, an anode AE22 of the second-second light emitting element ED22 may extend toward the second-second pixel circuit PC22. In an embodiment of the present disclosure, when the second-second pixel circuit PC22 is disposed on the right side with respect to the second-second light emitting element ED22, the anode AE22 of the second-second light emitting element ED22 may extend in the right direction. In embodiments, each of the second-second type pixels PX22 may further include a bridge electrode that connects the second-second light emitting element ED22 and the second-second pixel circuit PC22. The bridge electrode may be disposed in the same layer as the anode AE22 and may be integrally formed with the anode AE22. In an implementation, the bridge electrode may be disposed in a layer different from the layer in which the anode AE22 is disposed.

Each of the third-first type pixels PX31 includes a third-first pixel circuit PC31 and a third-first light emitting element ED31 connected to the third-first pixel circuit PC31, and each of the third-second type pixels PX32 includes a third-second pixel circuit PC32 and a third-second light emitting element ED32 connected to the third-second pixel circuit PC32. The third-first pixel circuit PC31 and the third-second pixel circuit PC32 are disposed in the second direction DR2 in alternating order. The third-first pixel circuit PC31 and the third-second pixel circuit PC32 are connected to the third type data line DLb. The third-first light emitting elements ED31 of the third-first type pixels PX31 are disposed in the first column, and the third-second light emitting elements ED32 of the third-second type pixels PX32 are disposed in the third column. The third-first pixel circuit PC31 may overlap the third-first light emitting element ED31 when viewed from above the plane, but the third-second pixel circuit PC32 may not overlap the third-second light emitting element ED32 when viewed from above the plane. Accordingly, an anode AE32 of the third-second light emitting element ED32 may extend toward the third-second pixel circuit PC32. In an embodiment of the present disclosure, when the third-second pixel circuit PC32 is disposed on the left side with respect to the third-second light emitting element ED32, the anode AE32 of the third-second light emitting element ED32 may extend in the left direction. In an embodiment, each of the third-second type pixels PX32 may further include a bridge electrode that connects the third-second light emitting element ED32 and the third-second pixel circuit PC32. The bridge electrode may be disposed in the same layer as the anode AE32 and may be integrally formed with the anode AE32. In an implementation, the bridge electrode may be disposed in a layer different from the layer in which the anode AE32 is disposed.

In an embodiment of the present disclosure, the first-first light emitting elements ED11 and the first-second light emitting elements ED12 are disposed in the first row. The third-first light emitting elements ED31 and the second-first light emitting elements ED21 are disposed in the second row. The first-first light emitting elements ED11 and the first-second light emitting

elements ED12 are disposed in the third row. The second-second light emitting elements ED22 and the third-second light emitting elements ED32 are disposed in the fourth row. The first-first light emitting elements ED11 and the first-second light emitting elements ED12 alternate with one another in the first row and the third row. The third-first light emitting elements ED31 and the second-first light emitting elements ED21 alternate with one another in the second row, and the second-second light emitting elements ED22 and the third-second light emitting elements ED32 alternate with one another in the fourth row. The arrangement of the first to fourth rows may be repeated in the second direction DR2.

The third-first light emitting elements ED31 and the second-second light emitting elements ED22 are disposed in the first column. The first-first light emitting elements ED11 are disposed in the second column. The second-first light emitting elements ED21 and the third-second light emitting elements ED32 are disposed in the third column. The first-second light emitting elements ED12 are disposed in the fourth column. The third-first light emitting elements ED31 and the second-second light emitting elements ED22 alternate with one another in the first column, and the second-first light emitting elements ED21 and the third-second light emitting elements ED32 alternate with one another in the third row.

Referring to FIGS. 10A and 10B, in the first mode, the display panel DP operates using a first pixel unit PXU1 and a second pixel unit PXU2. The first pixel unit PXU1 includes the first-first type pixel PX11, the first-second type pixel PX12, the second-first type pixel PX21, and the third-second type pixel PX32, and the second pixel unit PXU2 includes the first-first type pixel PX11, the first-second type pixel PX12, the second-second type pixel PX22, and the third-first type pixel PX31. In the first mode, the drive controller 100 may process (or, render) the image signal RGB to appropriately drive the first pixel unit PXU1 and the second pixel unit PXU2.

In the second mode, the display panel DP operates using a third pixel unit PXU3 having a configuration different from those of the first pixel unit PXU1 and the second pixel unit PXU2. The third pixel unit PXU3 includes two first-first type pixels PX11, the second-first type pixel PX21, and the third-first type pixel PX31. In the second mode, the drive controller 100 may process (or, render) the image signal RGB to appropriately drive the third pixel unit PXU3.

The light absorbing barrier walls LAW are disposed over the first-first light emitting element ED11, the second-first light emitting element ED21, and the third-first light emitting element ED31. The light absorbing barrier walls LAW are not disposed over the first-second light emitting element ED12, the second-second light emitting element ED22, and the third-second light emitting element ED32. The light absorbing barrier walls LAW may overlap the first-first light emitting element ED11, the second-first light emitting element ED21, and the third-first light emitting element ED31 when viewed from above the plane. Accordingly, when the display panel DP displays an image using only the first-first type pixel PX11, the second-first type pixel PX21, and the third-first type pixel PX31 in the second mode, the display panel DP may display the image at a viewing angle narrower than that in the first mode.

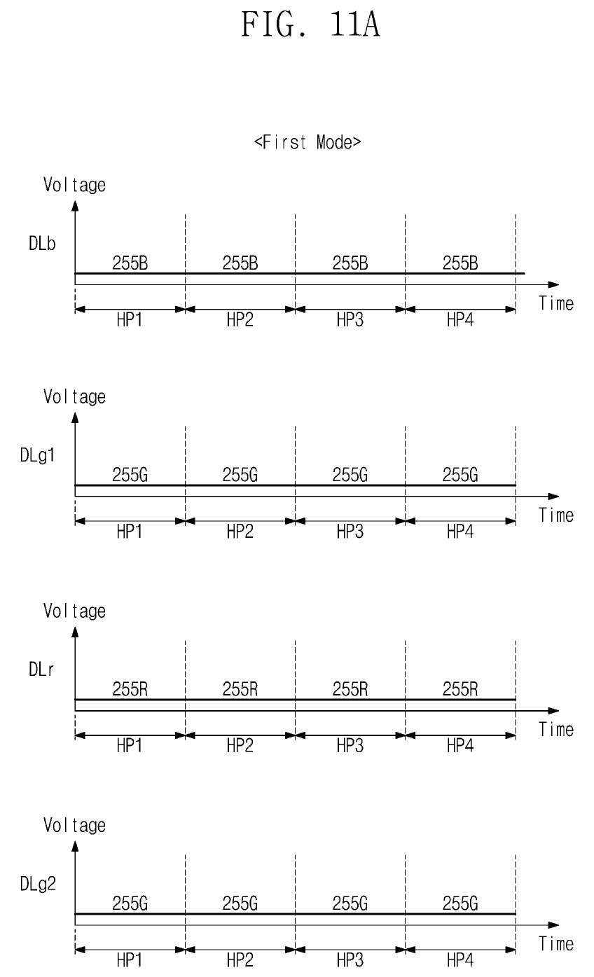

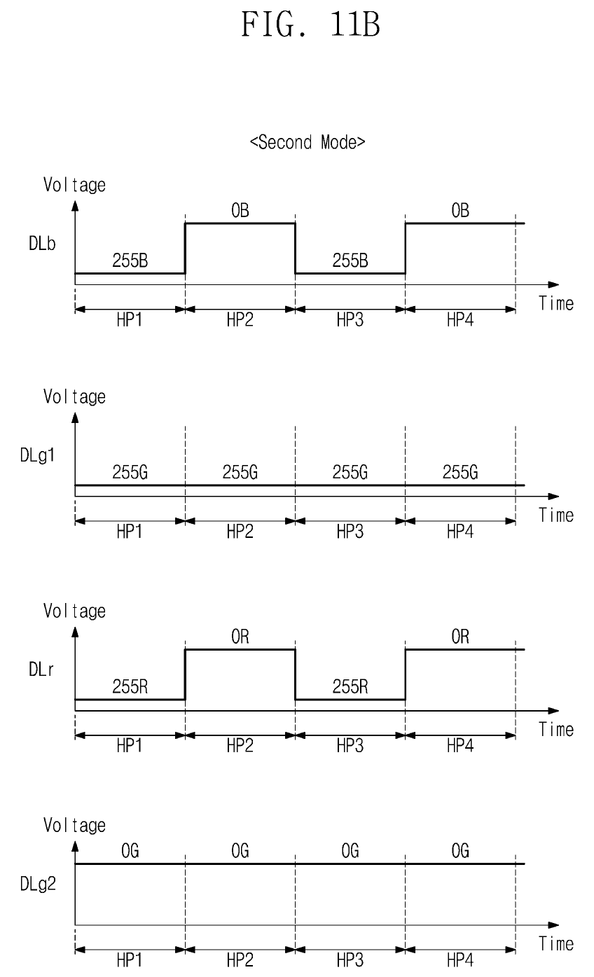

FIG. 11A illustrates waveform diagrams of data signals applied to the first-first type data line, the first-second type data line, the second type data line, and the third type data line in the first mode according to an embodiment of the present disclosure. FIG. 11B illustrates waveform diagrams of data signals applied to the first-first type data line, the first-second type data line, the second type data line, and the third type data line in the second mode according to an embodiment of the present disclosure.

Referring to FIGS. 10A and 11A, in the first mode, the first-first type data line DLg1, the second type data line DLr, the first-second type data line DLg2, and the third type data line DLb receive a first-first effective data signal, a second effective data signal, a first-second effective data signal, and a third effective data signal, respectively. In the first mode, the first-first type pixels PX11 and the first-second type pixels PX12 may output light of the first color having a grayscale value corresponding to the first-first effective data signal and the first-second effective data signal. In the first mode, the second-first type pixels PX21 and the second-second type pixels PX22 may output light of the second color having a grayscale value corresponding to the second effective data signal, and the third-first type pixels PX31 and the third-second type pixels PX32 may output light of the third color having a grayscale value corresponding to the third effective data signal.

When the first pixel unit PXU1 and the second pixel unit PXU2 display a white image in the first mode, the third type data line DLb may receive a blue data signal 255B having the grayscale value “255” as the third effective data signal during first to fourth horizontal scan periods HP1 to HP4.

When the first pixel unit PXU1 and the second pixel unit PXU2 display a white image in the first mode, the first-first type data line DLg1 may receive a green data signal 255G having the grayscale value “255” as the first-first effective data signal during the first to fourth horizontal scan periods HP1 to HP4. When the first pixel unit PXU1 and the second pixel unit PXU2 display a white image in the first mode, the first-second type data line DLg2 may receive a green data signal 255G having the grayscale value “255” as the first-second effective data signal during the first to fourth horizontal scan periods HP1 to HP4.

When the first pixel unit PXU1 and the second pixel unit PXU2 display a white image in the first mode, the second type data line DLr may receive a red data signal 255R having the grayscale value “255” as the second effective data signal during the first to fourth horizontal scan periods HP1 to HP4.

The second type data line DLr receives the red data signal 255R including red color information, and the third type data line DLb receives the blue data signal 255B including blue color information. That is, since the color information of the data signals applied to the second type data line DLr and the third type data line DLb does not change with time, power consumption may be reduced. Likewise, since the color information of the data signals applied to the first-first type data line DLg1 and the first-second type data line DLg2 does not change with time, power consumption may be reduced.

Referring to FIGS. 10B and 11B, in the second mode, the display panel DP displays an image using only the narrow pixels PX_N (refer to FIG. 6). In the second mode, the wide pixels PX_W (refer to FIG. 6) are not used to display the image. Accordingly, in the second mode, the first-first type data line DLg1 receives the first-first effective data signal, and the second type data line DLr receives the second effective data signal and a non-effective data signal in alternating order. In addition, in the second mode, the first-second type data line DLg2 receives a non-effective data signal and the third type data line DLb receives the third effective data signal and a non-effective data signal in alternating order.

When the third pixel unit PXU3 displays a white image in the second mode, the first-first type data line DLg1 may receive a green data signal 255G having the grayscale value “255” as the first-first effective data signal during the first to fourth horizontal scan periods HP1 to HP4. In the second mode, the first-second type data line DLg2 may receive a green data signal 0G having the grayscale value “0” as a non-effective data signal. The non-effective data signal may have a voltage level corresponding to the black grayscale.

In the second mode, the data signal applied to the first-first type data line DLg1 may be maintained as the first-first effective data signal, and the data signal applied to the first-second type data line DLg2 may be maintained as the non-effective data signal. Accordingly, in the second mode, a swing operation between an effective data signal and a non-effective data signal may be minimized, and thus power consumption may be reduced.

When the third pixel unit PXU3 displays a white image in the second mode, the third type data line DLb may receive a blue data signal 255B having the grayscale value “255” as the third effective data signal during the first horizontal scan period HP1 and the third horizontal scan period HP3. The third type data line DLb may receive a blue data signal 0B having the grayscale value “0” as a non-effective data signal during the second horizontal scan period HP2 and the fourth horizontal scan period HP4.

When the third pixel unit PXU3 displays a white image in the second mode, the second type data line DLr may receive a red data signal 255R having the grayscale value “255” as the second effective data signal during the first horizontal scan period HP1 and the third horizontal scan period HP3. The second type data line DLr may receive a red data signal 0R having the grayscale value “0” as a non-effective data signal during the second horizontal scan period HP2 and the fourth horizontal scan period HP4.

Although the data signals applied to the second type data line DLr and the third type data line DLb swing between the effective data signal and the non-effective data signal, the data signals applied to the first-first type data line DLg1 and the first-second type data line DLg2 are fixed as the effective data signal or the non-effective data signal, and a swing operation does not occur. Thus, overall power consumption may be reduced.

Although FIGS. 11A and FIG. 11B illustrate the case of expressing 256 grayscale values, the grayscale range expressed by each data signal may be modified in various ways. In addition, although FIGS. 11A and 11B illustrate an example that the non-effective data signal has a voltage level corresponding to the black grayscale (that is, the grayscale value “0”), the present disclosure is not limited thereto.

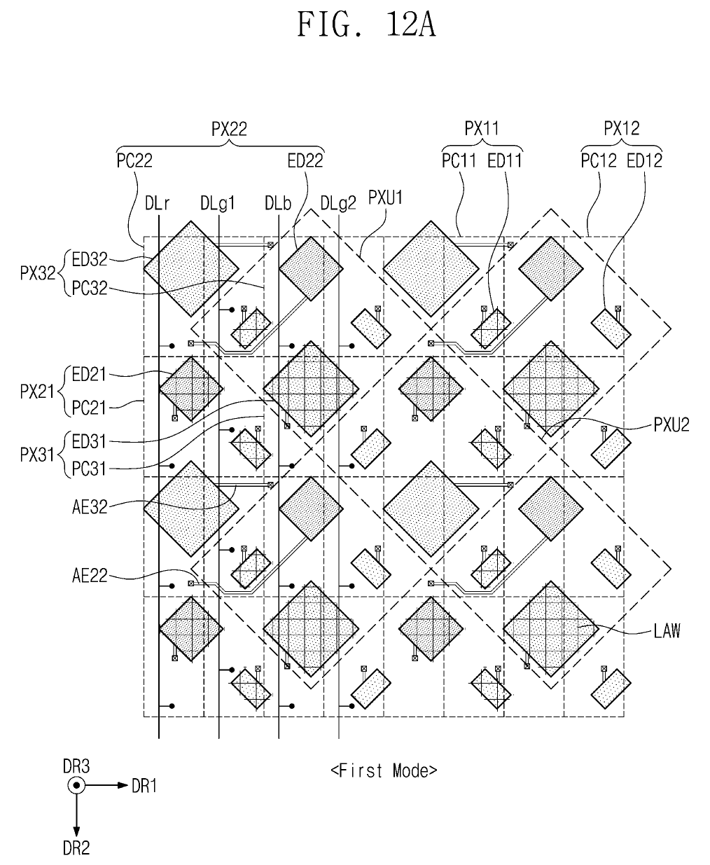

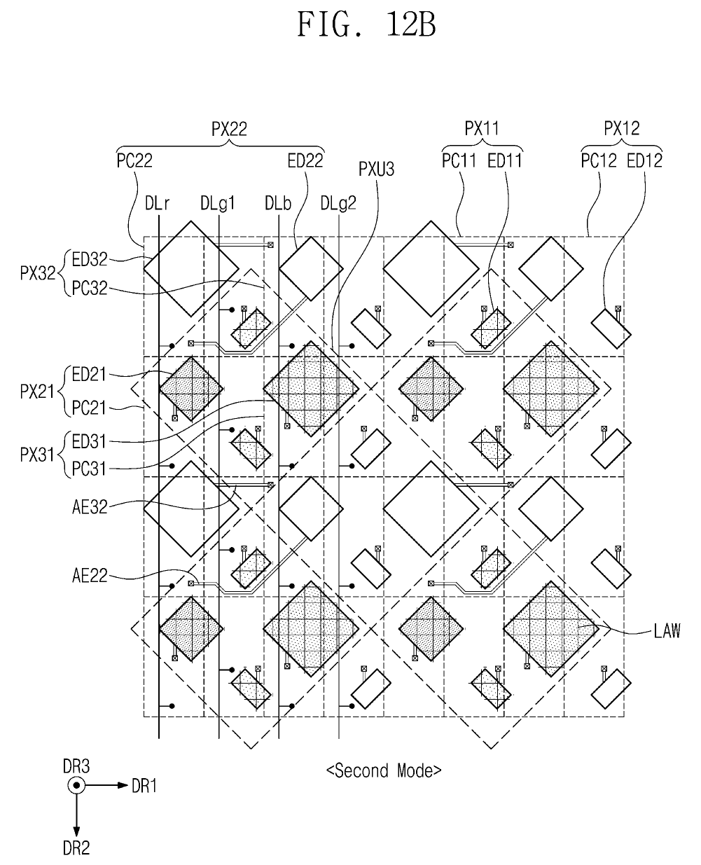

FIG. 12A is a view illustrating the display panel operating in the first mode according to an embodiment of the present disclosure. FIG. 12B is a view illustrating the display panel operating in the second mode according to an embodiment of the present disclosure. Among the components illustrated in FIGS. 12A and 12B, components identical to the components illustrated in FIGS. 8A and 8B will be assigned with identical reference numerals, and detailed description thereof will be omitted.

Referring to FIGS. 12A and 12B, first-first type pixels PX11 are connected to a first-first type data line DLg1, and first-second type pixels PX12 are connected to a first-second type data line DLg2. The second-first type pixels PX21 and second-second type pixels PX22 are connected to a second type data line DLr, and third-first type pixels PX31 and third-second type pixels PX32 are connected to a third type data line DLb. The second type data line DLr, the first-first type data line DLg1, the third type data line DLb, and the first-second type data line DLg2 may be sequentially disposed in the first direction DR1.

Each of the second-first type pixels PX21 includes a second-first pixel circuit PC21 and a second-first light emitting element ED21 connected to the second-first pixel circuit PC21, and each of the second-second type pixels PX22 includes a second-second pixel circuit PC22 and a second-second light emitting element ED22 connected to the second-second pixel circuit PC22. The second-first pixel circuit PC21 and the second-second pixel circuit PC22 are disposed in the second direction DR2 in alternating order. The second-first pixel circuit PC21 and the second-second pixel circuit PC22 are connected to the second type data line DLr. The second-first light emitting elements ED21 of the second-first type pixels PX21 are disposed in the first column, and the second-second light emitting elements ED22 of the second-second type pixels PX22 are disposed in the third column. The second-first pixel circuit PC21 may overlap the second-first light emitting element ED21 when viewed from above the plane, but the second-second pixel circuit PC22 may not overlap the second-second light emitting element ED22 when viewed from above the plane. Accordingly, an anode AE22 of the second-second light emitting element ED22 may extend toward the second-second pixel circuit PC22. In an embodiment of the present disclosure, when the second-second pixel circuit PC22 is disposed on the left side with respect to the second-second light emitting element ED22, the anode AE22 of the second-second light emitting element ED22 may extend in the left direction.

Each of third-first type pixels PX31 includes a third-first pixel circuit PC31 and a third-first light emitting element ED31 connected to the third-first pixel circuit PC31, and each of third-second type pixels PX32 includes a third-second pixel circuit PC32 and a third-second light emitting element ED32 connected to the third-second pixel circuit PC32. The third-first pixel circuit PC31 and the third-second pixel circuit PC32 are disposed in the second direction DR2 in alternating order. The third-first pixel circuit PC31 and the third-second pixel circuit PC32 are connected to the third type data line DLb. The third-first light emitting elements ED31 of the third-first type pixels PX31 are disposed in the third column, and the third-second light emitting elements ED32 of the third-second type pixels PX32 are disposed in the first column. The third-first pixel circuit PC31 may overlap the third-first light emitting element ED31 when viewed from above the plane, but the third-second pixel circuit PC32 may not overlap the third-second light emitting element ED32 when viewed from above the plane. Accordingly, an anode AE32 of the third-second light emitting element ED32 may extend toward the third-second pixel circuit PC32.

In an embodiment of the present disclosure, when the third-second pixel circuit PC32 is disposed on the right side with respect to the third-second light emitting element ED32, the anode AE32 of the third-second light emitting element ED32 may extend in the right direction.

In an embodiment of the present disclosure, the second-second light emitting elements ED22 and the third-second light emitting elements ED32 are disposed in the first row, and first-first light emitting elements ED11 and first-second light emitting elements ED12 are disposed in the second row. The third-first light emitting elements ED31 and the second-first light emitting elements ED21 are disposed in the third row, and the first-first light emitting elements ED11 and the first-second light emitting elements ED12 are disposed in the fourth row. The second-second light emitting elements ED22 and the third-second light emitting elements ED32 alternate with one another in the first row, the first-first light emitting elements ED11 and the first-second light emitting elements ED12 alternate with one another in the second row and the fourth row, and the third-first light emitting elements ED31 and the second-first light emitting elements ED21 alternate with one another in the third row. The arrangement of the first to fourth rows may be repeated in the second direction DR2.

The third-second light emitting elements ED32 and the second-first light emitting elements ED21 are disposed in the first column. The first-first light emitting elements ED11 are disposed in the second column. The second-second light emitting elements ED22 and the third-first light emitting elements ED31 are disposed in the third column. The first-second light emitting elements ED12 are disposed in the fourth column. The third-second light emitting elements ED32 and the second-first light emitting elements ED21 alternate with one another in the first column, and the second-second light emitting elements ED22 and the third-first light emitting elements ED31 alternate with one another in the third column. The first-first light emitting elements ED11 are arranged in the second direction DR2 along the first-first type data line DLg1, and the first-second light emitting elements ED12 are arranged in the second direction DR2 along the first-second type data line DLg2.

Referring to FIGS. 12A and 12B, in the first mode, the display panel DP operates using a first pixel unit PXU1 and a second pixel unit PXU2. The first pixel unit PXU1 includes the first-first type pixel PX11, the first-second type pixel PX12, the second-second type pixel PX22, and the third-first type pixel PX31, and the second pixel unit PXU2 includes the first-first type pixel PX11, the first-second type pixel PX12, the second-first type pixel PX21, and the third-second type pixel PX32. In the first mode, the drive controller 100 may process (or, render) the image signal RGB to appropriately drive the first pixel unit PXU1 and the second pixel unit PXU2.

In the second mode, the display panel DP operates using a third pixel unit PXU3 having a configuration different from those of the first pixel unit PXU1 and the second pixel unit PXU2. The third pixel unit PXU3 includes two first-first type pixels PX11, the second-first type pixel PX21, and the third-first type pixel PX31. In the second mode, the drive controller 100 may process (or, render) the image signal RGB to appropriately drive the third pixel unit PXU3.

The light absorbing barrier walls LAW are disposed over the first-first light emitting element ED11, the second-first light emitting element ED21, and the third-first light emitting element ED31. The light absorbing barrier walls LAW are not disposed over the first-second light emitting element ED12, the second-second light emitting element ED22, and the third-second light emitting element ED32. The light absorbing barrier walls LAW may overlap the first-first light emitting element ED11, the second-first light emitting element ED21, and the third-first light emitting element ED31 when viewed from above the plane. Accordingly, when the display panel DP displays an image using only the first-first type pixel PX11, the second-first type pixel PX21, and the third-first type pixel PX31 in the second mode, the display panel DP may display the image at a viewing angle narrower than that in the first mode.

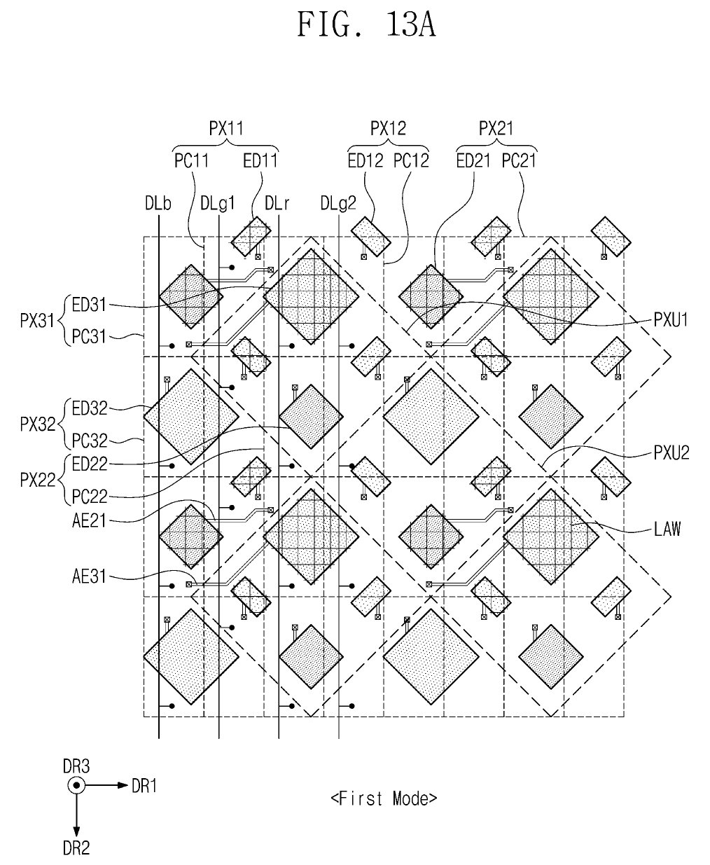

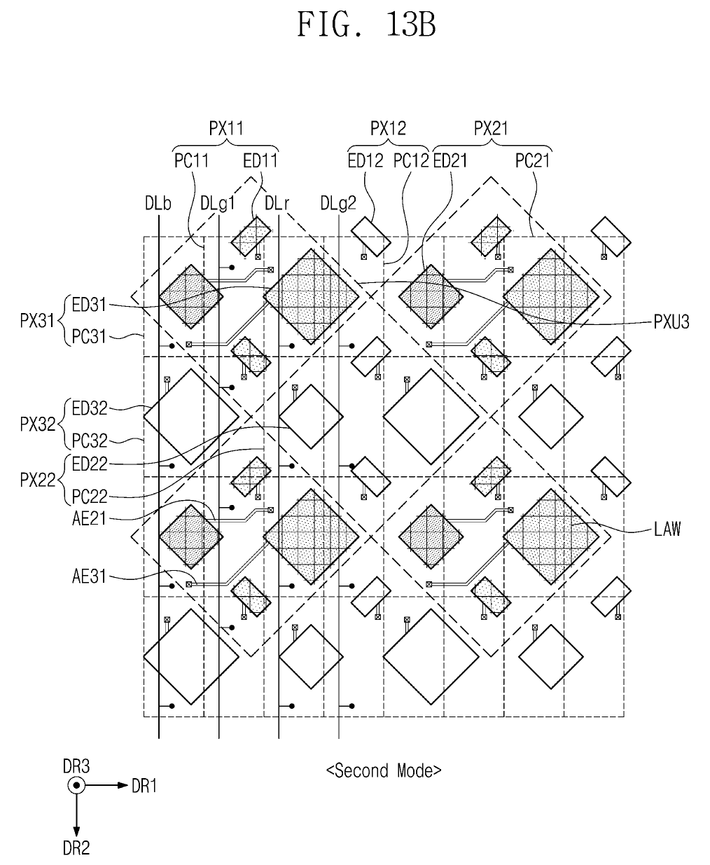

FIG. 13A is a view illustrating the display panel operating in the first mode according to an embodiment of the present disclosure. FIG. 13B is a view illustrating the display panel operating in the second mode according to an embodiment of the present disclosure. Among the components illustrated in FIGS. 13A and 13B, components identical to the components illustrated in FIGS. 10A and 10B will be assigned with identical reference numerals, and detailed description thereof will be omitted.

Referring to FIGS. 13A and 13B, first-first type pixels PX11 are connected to a first-first type data line DLg1, and first-second type pixels PX12 are connected to a first-second type data line DLg2. The second-first type pixels PX21 and second-second type pixels PX22 are connected to a second type data line DLr, and the third-first type pixels PX31 and third-second type pixels PX32 are connected to a third type data line DLb. The third type data line DLb, the first-first type data line DLg1, the second type data line DLr, and the first-second type data line DLg2 may be sequentially disposed in the first direction DR1.

Each of the first-first type pixels PX11 includes a first-first pixel circuit PC11 and a first-first light emitting element ED11 connected to the first-first pixel circuit PC11, and each of the first-second type pixels PX12 includes a first-second pixel circuit PC12 and a first-second light emitting element ED12 connected to the first-second pixel circuit PC12. The first-first pixel circuit PC11 may overlap the first-first light emitting element ED11 when viewed from above the plane, and the first-second pixel circuit PC12 may overlap the first-second light emitting element ED12 when viewed from above the plane. The first-first pixel circuits PC11 are connected to the first-first type data line DLg1, and the first-second pixel circuits PC12 are connected to the first-second type data line DLg2.

Each of the second-first type pixels PX21 includes a second-first pixel circuit PC21 and a second-first light emitting element ED21 connected to the second-first pixel circuit PC21, and each of the second-second type pixels PX22 includes a second-second pixel circuit PC22 and a second-second light emitting element ED22 connected to the second-second pixel circuit PC22. The second-first pixel circuit PC21 and the second-second pixel circuit PC22 are disposed in the second direction DR2 in alternating order. The second-first pixel circuit PC21 and the second-second pixel circuit PC22 are connected to the second type data line DLr. The second-first light emitting elements ED21 of the second-first type pixels PX21 are disposed in the first column, and the second-second light emitting elements ED22 of the second-second type pixels PX22 are disposed in the third column. The second-second pixel circuit PC22 may overlap the second-second light emitting element ED22 when viewed from above the plane, but the second-first pixel circuit PC21 may not overlap the second-first light emitting element ED21 when viewed from above the plane. Accordingly, an anode AE21 of the second-first light emitting element ED21 may extend toward the second-first pixel circuit PC21. In an embodiment of the present disclosure, when the second-first pixel circuit PC21 is disposed on the right side with respect to the second-first light emitting element ED21, the anode AE21 of the second-first light emitting element ED21 may extend in the right direction.

Each of third-first type pixels PX31 includes a third-first pixel circuit PC31 and a third-first light emitting element ED31 connected to the third-first pixel circuit PC31, and each of third-second type pixels PX32 includes a third-second pixel circuit PC32 and a third-second light emitting element ED32 connected to the third-second pixel circuit PC32. The third-first pixel circuit PC31 and the third-second pixel circuit PC32 are disposed in the second direction DR2 in

alternating order. The third-first pixel circuit PC31 and the third-second pixel circuit PC32 are connected to the third type data line DLb. The third-first light emitting elements ED31 of the third-first type pixels PX31 are disposed in the third column, and the third-second light emitting elements ED32 of the third-second type pixels PX32 are disposed in the first column. The third-second pixel circuit PC32 may overlap the third-second light emitting element ED32 when viewed from above the plane, but the third-first pixel circuit PC31 may not overlap the third-first light emitting element ED31 when viewed from above the plane. Accordingly, an anode AE31 of the third-first light emitting element ED31 may extend toward the third-first pixel circuit PC31. In an embodiment of the present disclosure, when the third-first pixel circuit PC31 is disposed on the left side with respect to the third-first light emitting element ED31, the anode AE31 of the third-first light emitting element ED31 may extend in the left direction.

In an embodiment of the present disclosure, the first-first light emitting elements ED11 and the first-second light emitting elements ED12 are disposed in the first row. The third-first light emitting elements ED31 and the second-first light emitting elements ED21 are disposed in the second row. The first-first light emitting elements ED11 and the first-second light emitting elements ED12 are disposed in the third row. The second-second light emitting elements ED22 and the third-second light emitting elements ED32 are disposed in the fourth row. The first-first light emitting elements ED11 and the first-second light emitting elements ED12 alternate with one another in the first row and the third row. The third-first light emitting elements ED31 and the second-first light emitting elements ED21 alternate with one another in the second row, and the second-second light emitting elements ED22 and the third-second light emitting elements ED32 alternate with one another in the fourth row. The arrangement of the first to fourth rows may be repeated in the second direction DR2.

The second-first light emitting elements ED21 and the third-second light emitting elements ED32 are disposed in the first column. The first-first light emitting elements ED11 are disposed in the second column. The third-first light emitting elements ED31 and the second-second light emitting elements ED22 are disposed in the third column. The first-second light emitting elements ED12 are disposed in the fourth column. The second-first light emitting elements ED21 and the third-second light emitting elements ED32 alternate with one another in the first column, and the third-first light emitting elements ED31 and the second-second light emitting elements ED22 alternate with one another in the third column.

Referring to FIGS. 13A and 13B, in the first mode, the display panel DP operates using a first pixel unit PXU1 and a second pixel unit PXU2. The first pixel unit PXU1 includes the first-first type pixel PX11, the first-second type pixel PX12, the second-second type pixel PX22, and the third-first type pixel PX31, and the second pixel unit PXU2 includes the first-first type pixel PX11, the first-second type pixel PX12, the second-first type pixel PX21, and the third-second type pixel PX32. In the first mode, the drive controller 100 may process (or, render) the image signal RGB to appropriately drive the first pixel unit PXU1 and the second pixel unit PXU2.

In the second mode, the display panel DP operates using a third pixel unit PXU3 having a configuration different from those of the first pixel unit PXU1 and the second pixel unit PXU2. The third pixel unit PXU3 includes two first-first type pixels PX11, the second-first type pixel PX21, and the third-first type pixel PX31. In the second mode, the drive controller 100 may process (or, render) the image signal RGB to appropriately drive the third pixel unit PXU3.

The light absorbing barrier walls LAW are disposed over the first-first light emitting element ED11, the second-first light emitting element ED21, and the third-first light emitting element ED31. The light absorbing barrier walls LAW are not disposed over the first- second light emitting element ED12, the second-second light emitting element ED22, and the third-second light emitting element ED32. The light absorbing barrier walls LAW may overlap the first-first light emitting element ED11, the second-first light emitting element ED21, and the third-first light emitting element ED31 when viewed from above the plane. Accordingly, when the display panel DP displays an image using only the first-first type pixel PX11, the second-first type pixel PX21, and the third-first type pixel PX31 in the second mode, the display panel DP may display the image at a viewing angle narrower than that in the first mode.

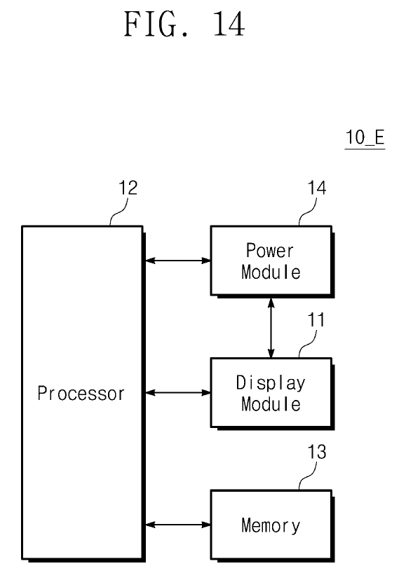

FIG. 14 is a block diagram of the electronic device according to an embodiment of the present disclosure.

Referring to FIG. 14, the electronic device 10_E according to an embodiment may include a display module 11, a processor 12, a memory 13, and a power module 14.

The processor 12 may control operation of the display module 11 and may include at least one selected from a central processing unit (CPU), an application processor (APU), a graphic processing unit (GPU), a communication processor (CP), an image signal processor (ISPU), and a controller. Additionally, the main processor, here, may be one or more processors. The one or more processors may perform operations, individually, as a collective or a as part of a collective, e.g. two processors out three processors may perform an operation together.

Data information utilized for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module, such as a power adaptor and/or a battery device, and a power conversion module that converts power supplied by the power supply module and generates power utilized for operation of the electronic device 10_E.

At least one of the components of the electronic device 10_E described above may be included in the display module according to the embodiments described above. In embodiments, some of the separate modules functionally included in one module may be included in the display module, and the other separate modules may be provided separately from the display module. For example, the display module 11 may be included in the display device, and the processor 12, the memory 13, and the power module 14 may be provided in the form of other devices within the electronic device 10 rather than the display device.

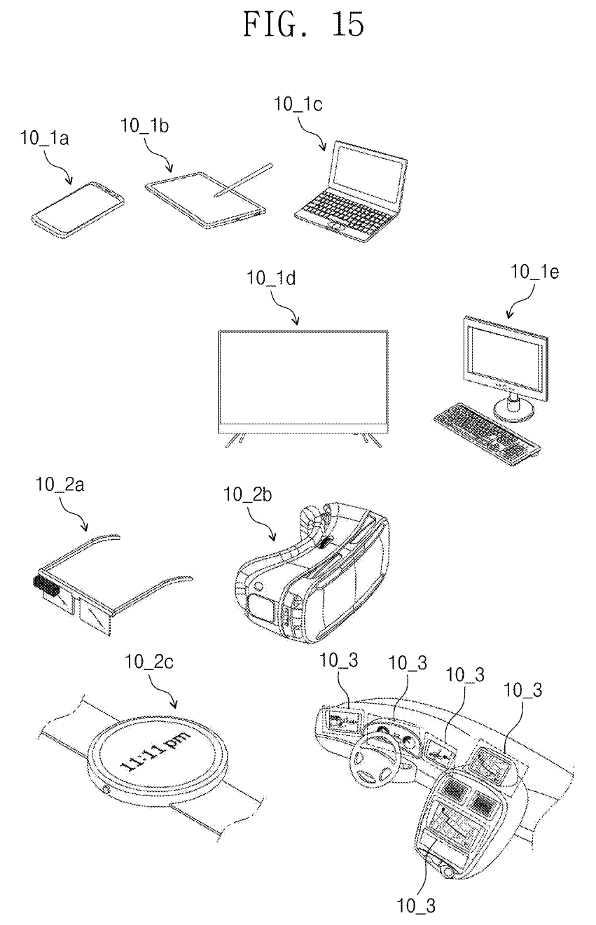

FIG. 15 illustrates schematic views of electronic devices according to various embodiments.

Referring to FIG. 15, the electronic devices according to the various embodiments, to which the display module is applied, may include not only an electronic device to display an image, such as a smart phone 10_1a, a tablet PC 10_1b, a laptop computer 10_1c, a TV 10_1d, or a desk monitor 10_1e, but also a wearable electronic device, such as smart glasses 10_2a, a head mounted display 10_2b, and/or a smart watch 10_2c, and a vehicle electronic device 10_3, such as a center information display (CID) and/or a room mirror display provided on an instrument panel, a center fascia, and/or a dashboard of a vehicle.

As described above, in the display panel operating in the first mode, the second type data line receives the red data signal including the red color information, and the third type data line receives the blue data signal including the blue color information. That is, since the color information of the data signals applied to the second type data line and the third type data line does not change with time, power consumption may be reduced. Likewise, since the color information of the data signals applied to the first-first type data line and the first-second type data line also does not change with time, power consumption may be reduced.

In addition, in the display panel operating in the second mode, the data signals applied to the second type data line and the third type data line swing between an effective data signal and a non-effective data signal. However, the data signal applied to the first-first type data line and the data signal applied to the first-second type data line are fixed as an effective data signal or a non-effective data signal. Thus, overall power consumption may be reduced.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a display panel; and
a panel driver configured to drive the display panel in a first mode or a second mode,
wherein the display panel includes:
first-first type pixels configured to output light of a first color;
first-second type pixels configured to output the light of the first color;
second-first type pixels configured to output light of a second color different from the light of the first color;
second-second type pixels configured to output the light of the second color;
a first-first type data line connected with the first-first type pixels;
a second type data line connected with the second-first type pixels and the second-second type pixels; and
a first-second type data line connected with the first-second type pixels,
wherein in the first mode, the first-first type data line receives a first-first effective data signal, the second type data line receives a second effective data signal, and the first-second type data line receives a first-second effective data signal and
wherein in the second mode, the first-first type data line receives the first-first effective data signal, the second type data line receives the second effective data signal and a non-effective data signal in alternating order, and the first-second type data line receives the non-effective data signal.

2. The electronic device of claim 1, wherein each of the first-first type pixels includes a first-first light emitting element, and each of the first-second type pixels includes a first-second light emitting element,
wherein the first-first light emitting element and the first-second light emitting element are spaced apart from each other in a first direction, and
wherein the first-first type data line, the second type data line, and the first-second type data line extend in a second direction perpendicular to the first direction.

3. The electronic device of claim 2, wherein the first-first type pixels include first-first pixel circuits arranged in the second direction, and the first-second type pixels include first-second pixel circuits arranged in the second direction,
wherein the first-first pixel circuits are connected with the first-first type data line, and
wherein the first-second pixel circuits are connected with the first-second type data line.

4. The electronic device of claim 2, wherein each of the second-first type pixels includes a second-first light emitting element and a second-first pixel circuit, and each of the second-second type pixels includes a second-second light emitting element and a second-second pixel circuit, and
wherein the second-first pixel circuit and the second-second pixel circuit are connected with the second type data line.

5. The electronic device of claim 4, wherein the second-first light emitting element does not overlap the second-first pixel circuit when viewed from above a plane,
wherein the second-second light emitting element overlaps the second-second pixel circuit when viewed from above the plane, and
wherein an anode of the second-first light emitting element extends toward the second-first pixel circuit.

6. The electronic device of claim 4, wherein the second-first light emitting element overlaps the second-first pixel circuit when viewed from above a plane,
wherein the second-second light emitting element does not overlap the second-second pixel circuit when viewed from above the plane, and
wherein an anode of the second-second light emitting element extends toward the second-second pixel circuit.

7. The electronic device of claim 1, wherein the display panel further includes:
third-first type pixels configured to output light of a third color different from the light of the first color and the light of the second color;
third-second type pixels configured to output the light of the third color; and
a third type data line connected with the third-first type pixels and the third-second type pixels.

8. The electronic device of claim 7, wherein in the first mode, the third type data line receives a third effective data signal, and
wherein in the second mode, the third type data line receives the third effective data signal and the non-effective data signal in alternating order.

9. The electronic device of claim 7, wherein the display panel operates using a first pixel unit and a second pixel unit in the first mode and operates using a third pixel unit in the second mode wherein the third pixel unit has a different configuration of pixels than configurations of pixels in the first pixel unit and the second pixel unit.

10. The electronic device of claim 9, wherein the first pixel unit includes a first-first type pixel, a first-second type pixel, a second-first type pixel, and a third-second type pixel,
wherein the second pixel unit includes a first-first type pixel, a first-second type pixel, a second-second type pixel, and a third-first type pixel, and
wherein the third pixel unit includes two first-first type pixels, a second-first type pixel, and a third-first type pixel.

11. The electronic device of claim 7, wherein the light of the first color is green light,
wherein the light of the second color is red light, and
wherein the light of the third color is blue light.

12. The electronic device of claim 1, wherein the non-effective data signal has a voltage level corresponding to a black grayscale.

13. The electronic device of claim 1, wherein the first mode is a mode configured to output an image at a first viewing angle, and
wherein the second mode is a mode configured to output the image at a second viewing angle narrower than the first viewing angle.

14. The electronic device of claim 13, further comprising:
an optical path control layer disposed over the display panel and configured to adjust a light output range of the light of the first color and the light of the second color output from the first-first type pixels and the second-first type pixels.

15. The electronic device of claim 14, wherein each of the first-first type pixels includes a first-first light emitting element, and each of the first-second type pixels includes a first-second light emitting element,
wherein each of the second-first type pixels includes a second-first light emitting element, and each of the second-second type pixels includes a second-second light emitting element, and
wherein the optical path control layer includes a light absorbing barrier wall disposed over the first-first light emitting elements and the second-first light emitting elements and configured to overlap the first-first light emitting elements and the second-first light emitting elements when viewed from above a plane.

16. An electronic device comprising:
a display panel; and
a panel driver configured to drive the display panel in a first mode or a second mode in response to a first mode enable signal or a second mode enable signal received from one or more main processors,
wherein the display panel includes:
a first-first type pixel configured to output light of a first color;
a first-second type pixel configured to output the light of the first color;
a second-first type pixel configured to output light of a second color different from the light of the first color;
a second-second type pixel configured to output the light of the second color;
a third-first type pixel configured to output light of a third color different from the light of the first color and the light of the second color; and
a third-second type pixel configured to output the light of the third color,
wherein the display panel operates using a first pixel unit and a second pixel unit in the first mode and operates using a third pixel unit having a configuration different from configurations of the first pixel unit and the second pixel unit in the second mode,
wherein the first pixel unit includes the first-first type pixel, the first-second type pixel, the second-first type pixel, and the third-second type pixel,
wherein the second pixel unit includes the first-first type pixel, the first-second type pixel, the second-second type pixel, and the third-first type pixel, and
wherein the third pixel unit includes two first-first type pixels, the second-first type pixel, and the third-first type pixel.

17. The electronic device of claim 16, wherein the first-first type pixel includes a first-first light emitting element, and the first-second type pixel includes a first-second light emitting element,
wherein the second-first type pixel includes a second-first light emitting element, and the second-second type pixel includes a second-second light emitting element, and
wherein the third-first type pixel includes a third-first light emitting element, and the third-second type pixel includes a third-second light emitting element.

18. The electronic device of claim 17, wherein the first-first light emitting element and the first-second light emitting element are spaced apart from each other in a first direction,
wherein the second-first light emitting element and the third-second light emitting element are adjacent to each other in a second direction perpendicular to the first direction, and
wherein the second-second light emitting element and the third-first light emitting element are adjacent to each other in the second direction.

19. The electronic device of claim 17, wherein the first-first type pixel further includes a first-first pixel circuit, and the first-second type pixel further includes a first-second pixel circuit,
wherein the second-first type pixel further includes a second-first pixel circuit, and the second-second type pixel further includes a second-second pixel circuit, and
wherein the third-first type pixel further includes a third-first pixel circuit, and the third-second type pixel further includes a third-second pixel circuit.

20. The electronic device of claim 19, wherein the display panel further includes:
a first-first type data line connected to the first-first pixel circuit;
a second type data line connected to the second-first pixel circuit and the second-second pixel circuit;
a first-second type data line connected to the first-second pixel circuit; and
a third type data line connected to the third-first pixel circuit and the third-second pixel circuit.
